(19) United States
(12) Patent Application Publication
(10) Pub. No.: US 2024/0260414 A1
(43) Pub. Date: Aug. 1, 2024

(54) Light Emitting Diode Display Device

(71) Applicant: LG Display Co., Ltd., Seoul (KR)

(72) Inventors: Seongyong Cho, Paju-si (KR); Taeyoung Heo, Paju-si (KR)

(21) Appl. No.: 18/520,363

(22) Filed: Nov. 27, 2023

(30) Foreign Application Priority Data
Jan. 27, 2023 (KR) 10-2023-0010785

(51) Int. Cl. H10K 59/80

(52) U.S. Cl. CPC H10K 59/877; H10K 59/879

(57) ABSTRACT

Disclosed is a light emitting diode display device comprising a light emitting diode provided on a substrate, a lens provided on the light emitting diode and configured to have a convex curved surface, and a scattering pattern configured to have an opening area exposing at least a portion of the curved surface of the lens.

### CROSS REFERENCE OF RELATED APPLICATION

This application claims the benefit of Republic of Korea Patent Application No. 10-2023-0010785 filed Jan. 27, 2023, which is incorporated herein by reference in its entirety.

### BACKGROUND

### Technical Field

The present disclosure relates to a display device, and more particularly, to a light emitting diode display device.

### Description of the Related Art

A display device is widely used as a display screen of a laptop computer, a tablet computer, a smart phone, a portable display device, and a portable information device in addition to a display screen of a television or a monitor. A liquid crystal display device and an organic light emitting display device display an image by the use of thin film transistor serving as a switching element. As the liquid crystal display device has a backlight unit, there is a limitation in design, and luminance and response speed may be reduced. Since the organic light emitting display device includes an organic material, the organic light emitting display device is vulnerable to moisture, whereby reliability and lifespan thereof may deteriorate.

Recently, research and development of a light emitting diode display device using a micro light emitting diode has been conducted, and the light emitting diode display device has high quality and high reliability, whereby it is spotlighted as a next generation display device.

### SUMMARY

The present disclosure has been made in view of the above problems, and it is an object of the present disclosure to provide a light emitting diode display device capable of improving a front luminance.

It is another object of the present disclosure to provide a light emitting diode display device capable of improving a light extraction efficiency.

In accordance with an aspect of the present disclosure, the above and other objects may be accomplished by the provision of a light emitting diode display device comprising a light emitting diode provided over a substrate, a lens provided over the light emitting diode and configured to have a convex curved surface, and a scattering pattern configured to have an opening area exposing at least a portion of the curved surface of the lens.

In addition to the effects of the present disclosure as mentioned above, additional advantages and features of the present disclosure will be clearly understood by those skilled in the art from the above description of the present disclosure.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view schematically illustrating a light emitting diode display device according to one embodiment of the present disclosure;

FIG. 2 is a plan view illustrating an example of a unit pixel, a lens, and a scattering pattern provided in a display area according to one embodiment of the present disclosure;

FIG. 3 is a cross sectional view illustrating an example along I-I′ of FIG. 2 according to one embodiment of the present disclosure;

FIG. 4 is a diagram for describing an example of a path of light passing through a lens and a scattering pattern according to one embodiment of the present disclosure;

FIG. 5 is a diagram for describing a thickness of a fourth planarization layer according to one embodiment of the present disclosure;

FIG. 6 is a diagram for describing a thickness of a scattering pattern according to one embodiment of the present disclosure;

FIG. 7A is a table showing simulation input conditions according to one embodiment of the present disclosure;

FIG. 7B is a diagram illustrating a result of simulating a second angle change for each thickness of a scattering pattern according to the simulation input conditions shown in FIG. 7A according to one embodiment of the present disclosure;

FIG. 8 is a plan view illustrating an example in which a scattering pattern is modified in FIG. 2 according to one embodiment of the present disclosure;

FIG. 9A is a table showing simulation input conditions according to one embodiment of the present disclosure;

FIG. 9B is a diagram illustrating a result of simulating changes in luminance for each viewing angle according to the simulation input conditions shown in FIG. 9A according to one or more embodiments of the present disclosure;

FIG. 9C is a diagram illustrating a result of simulating front luminance and total extracted light amount according to the simulation input conditions shown in 9A according to one or more embodiments of the present disclosure;

FIG. 10A is a diagram illustrating a result of simulating changes in luminance for each viewing angle with respect to various thicknesses of the scattering pattern according to one embodiment of the present disclosure;

FIG. 10B shows a result of simulating front luminance and total extracted light amount with respect to various thicknesses of the scattering pattern according to one embodiment of the present disclosure;

FIG. 11 is a cross sectional view along line I-I′ of FIG. 2 according to one embodiment of the present disclosure;

FIG. 12 is a cross sectional view illustrating a modified example along I-I′ of FIG. 2 according to one embodiment of the present disclosure; and

FIG. 13 is a cross sectional view illustrating another modified example along I-I′ of FIG. 2 according to one embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a dimension (e.g., length, width, height, thickness, radius, diameter, area, etc.), a ratio, an angle, and a number of elements disclosed in the drawings for describing embodiments of the present disclosure are merely an example, and thus, the present disclosure is not limited to the illustrated details.

A dimension including a size and a thickness of each component illustrated in the drawing are illustrated for convenience of description, and the present disclosure is not limited to the size and the thickness of the component illustrated, but it is to be noted that the relative dimensions including the relative size, location and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted. In a case where ‘comprise,’ ‘have,’ and ‘include’ described in the present specification are used, another part may be added unless ‘only-’ is used. The terms of a singular form may include plural forms unless referred to the contrary.

In construing an element, the element is construed as including an error range although there is no explicit description.

In describing a position relationship, for example, when the position relationship is described as ‘upon˜,’ ‘above˜,’ ‘below˜,’ and ‘next to˜,’ one or more portions may be arranged between two other portions unless ‘just’ or ‘direct’ is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” etc., may be used. These terms are intended to identify the corresponding elements from the other elements, and basis, order, or number of the corresponding elements are not limited by these terms. The expression that an element is “connected” or “coupled” to another element should be understood that the element may directly be connected or coupled to another element but may indirectly be connected or coupled to another element unless specially mentioned, or a third element may be interposed between the corresponding elements.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

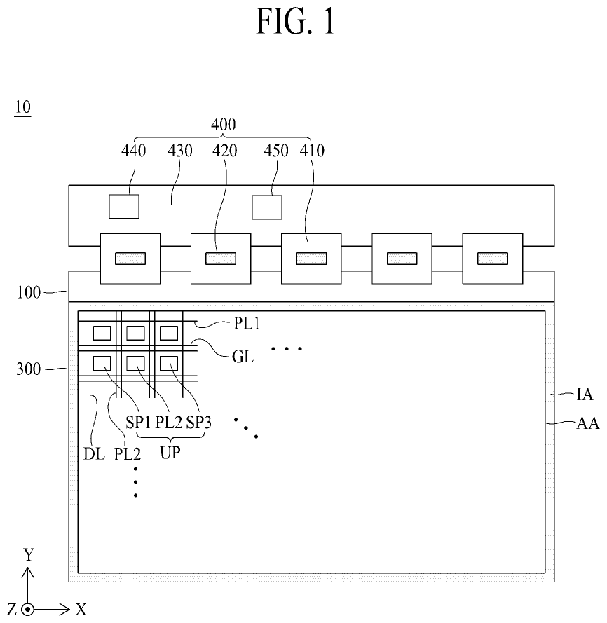

FIG. 1 is a plan view schematically illustrating a light emitting diode display device according to one embodiment of the present disclosure.

Hereinafter, for example, X axis indicates a line parallel with a gate line, Y axis indicates a line parallel with a data line, and Z axis indicates a height direction of a light emitting diode display device.

Referring to FIG. 1, the light emitting diode display device according to one embodiment of the present disclosure includes a first substrate 100, a plurality of unit pixels UP, and a second substrate 300.

The first substrate 100 is a thin film transistor array substrate and may include glass or a plastic material. The first substrate 100 may be divided into a display area AA and a non-display area IA.

The non-display area IA is an area in which an image is not displayed, and the non-display area IA corresponds to an area excluding the display area AA. The non-display area IA is an edge area of the first substrate 100 surrounding the display area AA, wherein the non-display area IA may have a relatively narrow width, and may be defined as a bezel area. A wiring and a circuit for driving the plurality of unit pixels UP in the display area AA may be disposed in the non-display area IA.

The display area AA is an area in which the plurality of unit pixels UP are provided to display an image, and the display area AA corresponds to the remaining area except for the edge area of the first substrate 100.

The plurality of unit pixels UP are provided in the display area AA. The plurality of unit pixels UP may be arranged in such a way that each of the plurality of unit pixels UP has a first reference pixel distance preset along a first direction (e.g., X-axis direction) and has a second reference pixel distance preset along a second direction (e.g., Y-axis direction) in the display area AA. Herein, the first reference pixel distance may be defined as a distance between the centers of two adjacent unit pixels UP along the first direction (e.g., X-axis direction), and the second reference pixel distance may be defined as a distance between the centers of two adjacent unit pixels along the second direction (e.g., Y-axis direction).

Each of the plurality of unit pixels UP may include a plurality of subpixels SP1, SP2, and SP3. For example, each of the plurality of unit pixels UP may include a red subpixel S1 configured to emit red light, a green subpixel SP2 configured to emit green light, and a blue subpixel SP3 configured to emit blue light. In another example, each of the plurality of unit pixels UP may include a white subpixel configured to emit white light.

The first substrate 100 may be provided with pixel driving lines together with the plurality of unit pixels UP in the display area AA.

The pixel driving lines are provided over a front surface of the first substrate 100 and configured to supply signals required for each of the plurality of subpixels SP1, SP2, and SP3. According to one embodiment, the pixel driving lines may include a plurality of gate lines GL, a plurality of data lines DL, a plurality of driving power lines PL2, and a plurality of common power lines PL1.

The plurality of gate lines GL may extend in the first direction (e.g., X-axis direction) on the front surface of the first substrate 100 and may be spaced apart from each other in the second direction (e.g., Y-axis direction). Each of the plurality of gate lines GL may supply a scan signal to the plurality of subpixels SP1, SP2, and SP3.

The plurality of data lines DL may be disposed to intersect the plurality of gate lines GL on the front surface of the first substrate 100. The plurality of data lines DL may extend in the second direction (e.g., Y-axis direction) and may be spaced apart from each other in the first direction (e.g., X-axis direction). Each of the plurality of data lines DL may supply a data voltage to the plurality of subpixels SP1, SP2, and SP3.

The plurality of driving power lines PL2 may be arranged in parallel with the plurality of data lines DL on the front surface of the first substrate 100. Each of the plurality of driving power lines PL2 may supply a pixel driving power provided from the outside to the adjacent subpixels SP1, SP2, and SP3.

The plurality of common power lines PL1 may be arranged in parallel with each of the plurality of gate lines GL on the front surface of the first substrate 100. Each of the plurality of common power lines PL1 may supply common power provided from the outside to the adjacent subpixels SP1, SP2, and SP3.

Each of the subpixels SP1, SP2, and SP3 is provided in a subpixel area defined by the gate line GL and the data line DL. Each of the plurality of subpixels SP1 to SP3 may be defined as a minimum unit area in which light is emitted virtually.

According to one embodiment, the light emitting diode display device may further include a scan driver and a panel driver 400.

The scan driver generates a scan pulse according to a gate control signal inputted from the panel driver 400 and supplies the scan pulse to the gate line GL. The scan driver may be provided in the non-display area at the left and/or right side of the display area AA or may be provided in the display area AA. The scan driver may be provided in the arbitrary non-display area IA or display area AA capable of supplying the scan pulse to the gate line GL. The scan driver may be formed by a gate driver in panel GIP method, a gate driver in active area GIA method, or a tape automated bonding TAB method.

The panel driver 400 is connected to a pad portion prepared in the non-display area IA of the first substrate 100 and is configured to display an image corresponding to image data supplied from a host system on the display area AA. The panel driver 400 according to one embodiment may include a plurality of data flexible circuit films 410, a plurality of data driving integrated circuits 420, a printed circuit board 430, a timing controller 440, and a power supply circuit 450.

Each of the plurality of data flexible circuit films 410 may be attached to the pad portion of the first substrate 100 by a film attaching process. Each of the plurality of data driving integrated circuits 420 may be individually mounted on each of the plurality of data flexible circuit films 410. The data driving integrated circuit 420 receives pixel data and a data control signal provided from the timing controller 440, converts the pixel data into a data voltage for each pixel in an analog form according to the data control signal, and supplies the data voltage to the corresponding data line DL.

The timing controller 440 is mounted on the printed circuit board 430 and receives image data and a timing synchronization signal provided from the host system. The timing controller 440 generates pixel data by aligning image data to be suitable for a pixel arrangement structure of the display area AA based on the timing synchronization signal, and provides the generated pixel data to the data driving integrated circuit 420. In addition, the timing controller 440 may generate each of a data control signal and a gate control signal based on the timing synchronization signal to control the driving timing of each of the plurality of data driving integrated circuits 420 and the scan driver.

The power supply circuit 450 is mounted on the printed circuit board 430 and generates various voltages necessary for displaying an image in the display area AA by using an input power input from the outside and supplies the generated voltages to a corresponding configuration.

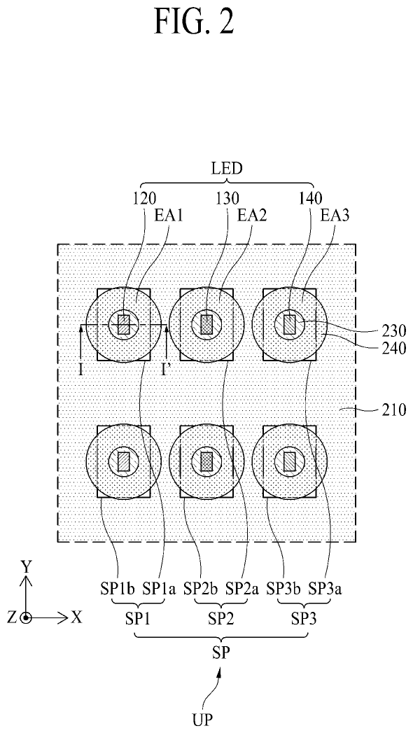

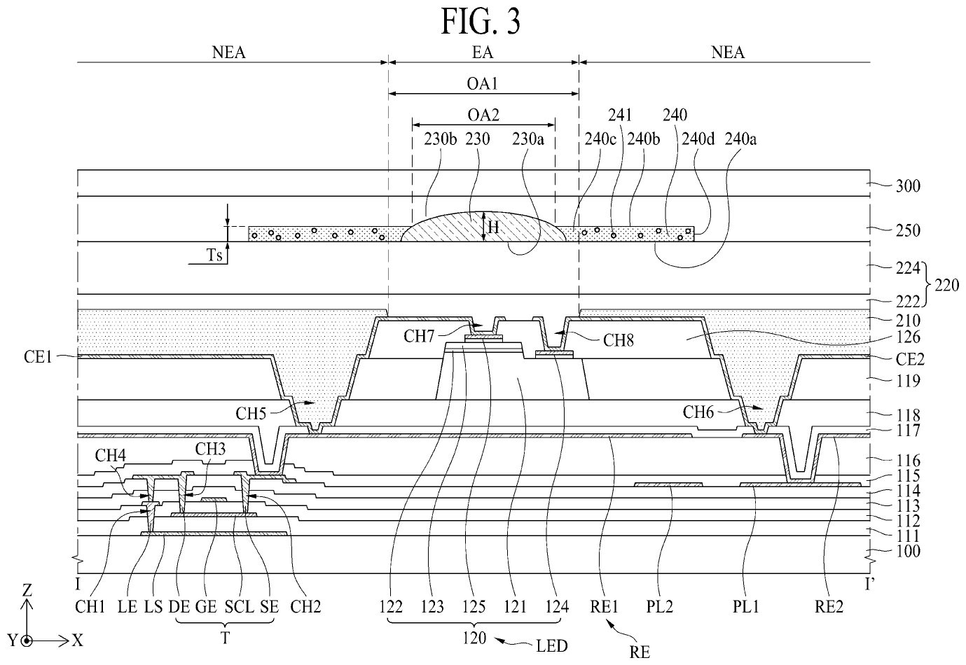

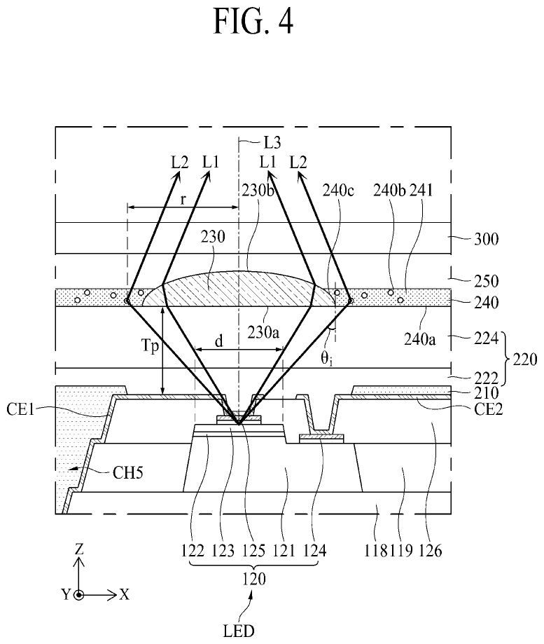

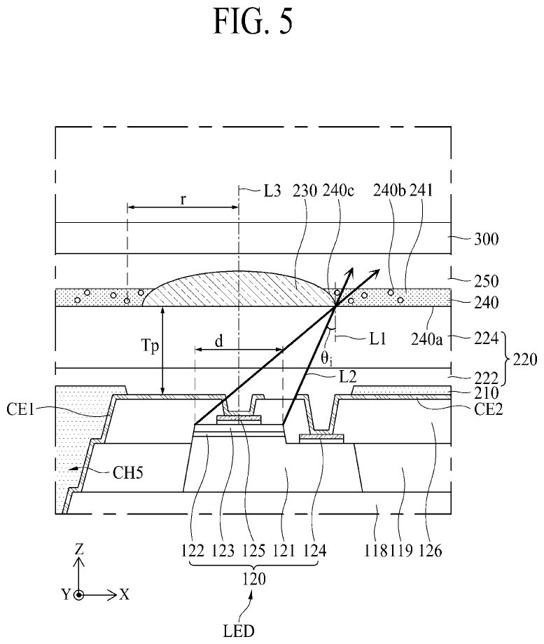

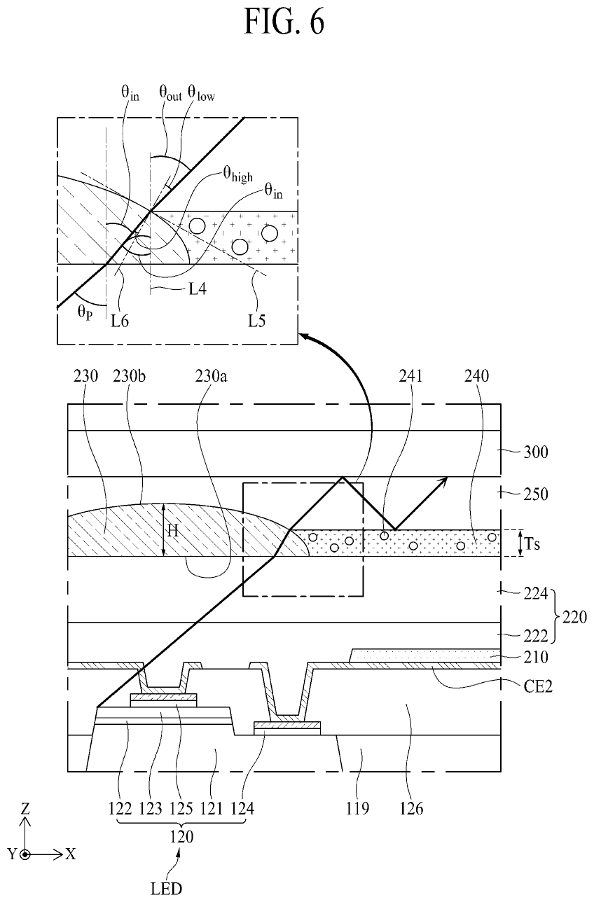

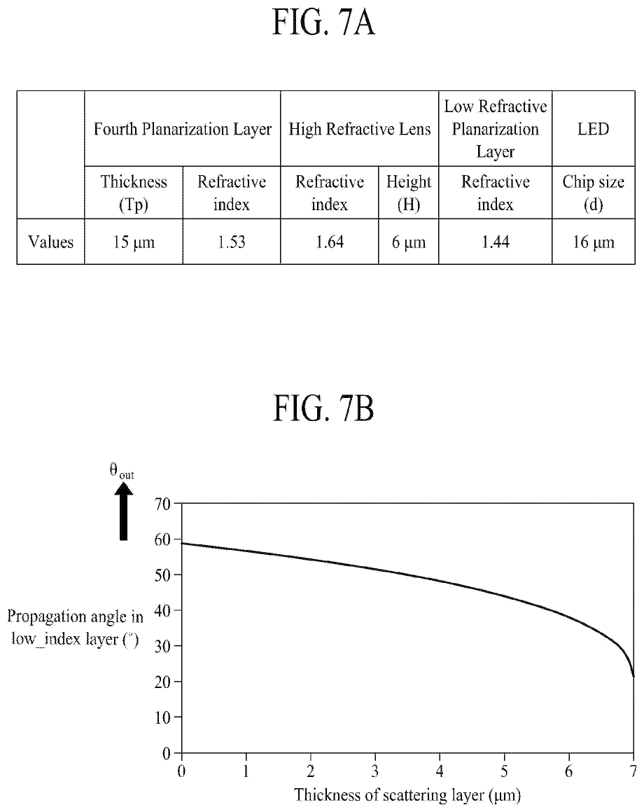

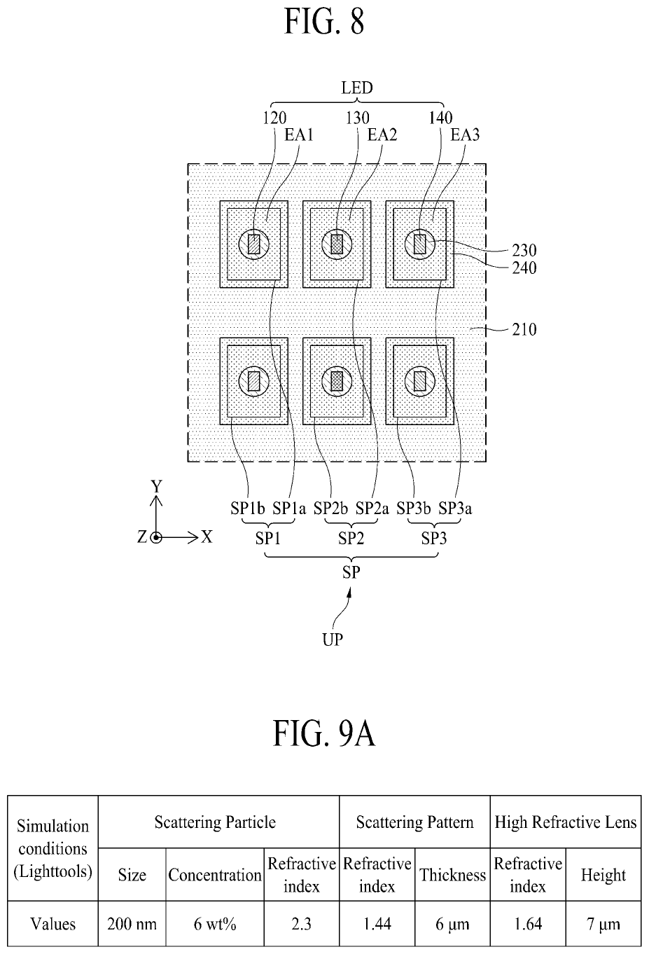

FIG. 2 is a plan view illustrating an example of a unit pixel, a lens, and a scattering pattern provided in a display area. FIG. 3 is a cross sectional view illustrating an example along I-I′ of FIG. 2. FIG. 4 is a diagram for describing an example of a path of light passing through a lens and a scattering pattern. FIG. 5 is a diagram for describing a thickness of a fourth planarization layer. FIG. 6 is a diagram for describing a thickness of a scattering pattern. FIG. 7A is a table showing simulation input conditions. FIG. 7B is a diagram illustrating a result of simulating a second angle change for each thickness of a scattering pattern according to the simulation input conditions shown in FIG. 7A. FIG. 8 is a plan view illustrating an example in which a scattering pattern is modified in FIG. 2.

A light emitting diode display device according to one embodiment of the present disclosure includes a plurality of unit pixels UP in a display area AA, and each of the plurality of unit pixels UP includes a first subpixel SP1, a second subpixel SP2, and a third subpixel SP3, as shown in FIG. 2.

The first subpixel SP1 may include a first light emitting area EA1 emitting first color light, the second subpixel SP2 may include a second light emitting area EA2 emitting second color light, and the third subpixel SP3 may include a third light emitting area EA3 emitting third color light.

For example, all first to third light emitting areas EA1, EA2, and EA3 may emit light of different colors. For example, the first light emitting area EA1 may emit red light, the second light emitting area EA2 may emit green light, and the third light emitting area EA3 may emit blue light. In addition, an arrangement order of the respective subpixels SP1, SP2, and SP3 may be variously changed.

According to one embodiment, each of the plurality of unit pixels may further include a white subpixel for emitting white light to improve luminance.

A first subpixel SP1, a second subpixel SP2, and a third subpixel SP3 may be respectively provided in each of a plurality of unit pixels UP, but not limited thereto. In another embodiment, at least one of a first subpixel SP1, a second subpixel SP2, and a third subpixel SP3, for example, two subpixels may be provided in each unit pixel UP. For example, as shown in FIG. 2, one unit pixel may include two first subpixels SP1, two second subpixels SP2, and two third subpixels SP3. The first subpixel SP1 includes a (1-1)th subpixel SP1a and a (1-2)th subpixel SP1b, and the second subpixel SP2 includes a (2-1)th subpixel SP2a and a (2-2)th subpixel SP2b, and the third subpixel SP3 may include a (3-1)th subpixel SP3a and a (3-2)th subpixel SP3b.

Each of the plurality of subpixels SP1, SP2, and SP3 includes a pixel circuit. The pixel circuit may be provided in a circuit region defined in the subpixel SP1, SP2, and SP3 and may be connected to an adjacent gate line GL, a data line DL, and a second power line PL2. The pixel circuit controls a current flowing in a light emitting diode LED according to a data signal from the data line DL in response to a scan pulse from the gate line GL based on a pixel driving power supplied from the second power line PL2. The pixel circuit may include at least one transistor and capacitor.

The at least one transistor may include a driving transistor T and switching transistors. The switching transistor may be switched according to the scan pulse supplied to the gate line GL to charge the capacitor with a data voltage supplied from the data line DL.

The driving transistor T is switched according to the voltage supplied from the switching transistor or the data voltage charged in the capacitor, thereby generating a data current from power source supplied from the second power line PL2 and supplying the data current to the light emitting diode LED of the subpixels SP1, SP2, and SP3.

The light emitting diode display device 10 may include a driving transistor T, a plurality of insulating layers, a light emitting diode LED, a first connection electrode CE1, a second connection electrode CE2, a lens 230, a scattering pattern 240, a fifth planarization layer 250, and a second substrate 300 as shown in FIG. 3.

In detail, a light shielding layer LS may be provided over a first substrate 100. The light shielding layer LS may block light incident on a semiconductor layer SCL of the driving transistor T. Light incident on the semiconductor layer SCL of the driving transistor T is blocked in the light shielding layer LS, thereby minimizing or at least reducing a leakage current.

A buffer layer 111 may be provided over the light shielding layer LS. The buffer layer 111 may reduce penetration of moisture or impurities through the first substrate 100. For example, the buffer layer 111 may be composed of a single layer or multiple layers of silicon oxide SiOx or silicon nitride SiNx, but not limited thereto. However, the buffer layer 111 may be omitted depending on the type of the first substrate 100 or the type of transistor, but not limited thereto.

The driving transistor T may be provided over the buffer layer 111. The driving transistor T may include a gate electrode GE, a semiconductor layer SCL, a source electrode SE, and a drain electrode DE.

The semiconductor layer SCL of the driving transistor T may be provided over the buffer layer 111. The semiconductor layer SCL may be formed of a semiconductor material such as oxide semiconductor, amorphous silicon, or polysilicon, but not limited thereto.

A gate insulating layer 112 may be provided over the semiconductor layer SCL. The gate insulating layer 112 may be formed of an inorganic layer, for example, a silicon oxide layer SiOx, a silicon nitride layer SiNx, or a multilayer thereof.

The gate electrode GE of the driving transistor T may be provided over the gate insulation layer 112. The gate electrode GE may include a single layer or multiple layers of any one of molybdenum Mo, aluminum Al, chromium Cr, gold Au, titanium Ti, nickel Ni, neodymium Nd, and copper Cu, or an alloy thereof.

A first insulating interlayer 113 and a second insulating interlayer 114 may be disposed over the gate electrode GE. A contact hole for connecting each of the source electrode SE and the drain electrode DE to the semiconductor layer SCL may be formed in the first insulating interlayer 113 and the second insulating interlayer 114. The first insulating interlayer 113 and the second insulating interlayer 114 are insulating layers for protecting the components under the first insulating interlayer 113 and the second insulating interlayer 114. The first insulating interlayer 113 and the second insulating interlayer 114 may include a single layer or multilayers of silicon oxide SiOx or silicon nitride SiNx, but not limited thereto.

The source electrode SE and drain electrode DE of the driving transistor T may be provided over the second insulating interlayer 114. The source electrode SE is connected to the semiconductor layer SCL through a second contact hole CH2 passing through the first insulating interlayer 113 and the second insulating interlayer 114, and the drain electrode DE is connected to the semiconductor layer SCL through a third contact hole CH3 passing through the first insulating interlayer 113 and the second insulating interlayer 114. The source electrode SE and the drain electrode DE may be formed of a single layer or multiple layers of any one of molybdenum Mo, aluminum Al, chromium Cr, gold Au, titanium Ti, nickel Ni, neodymium Nd, and copper Cu, or an alloy thereof.

According to the present disclosure, a first insulating interlayer 113 and a second insulating interlayer 114, that is, the plurality of insulating layers are disposed between the gate electrode GE and the source electrode SE/drain electrode DE, but not necessarily. For example, only one insulating layer may be disposed between the gate electrode GE and the source electrode SE/drain electrode DE, but not limited thereto.

When the plurality of insulating layers such as the first insulating interlayer 113 and the second insulating interlayer 114 are disposed between the gate electrode GE and the source electrode SE/drain electrode DE as shown in the drawings, an electrode may be additionally formed between the first insulating interlayer 113 and the second insulating interlayer 114. The additionally provided electrode may form a capacitor together with other elements disposed below the first insulating interlayer 113 or above the second insulating interlayer 114.

An auxiliary electrode LE may be disposed over the gate insulating layer 112. The auxiliary electrode LE may be an electrode for electrically connecting the light shielding layer LS provided thereunder to any one electrode of the source electrode SE and drain electrode DE over the second insulating interlayer 114. For example, since the light shielding layer LS is electrically connected to any one of the source electrode SE or the drain electrode DE through the auxiliary electrode LE and is not operated as a floating gate, it is possible to minimize or at least reduce a threshold voltage variation of the driving transistor T generated by the floated light shielding layer LS. In the drawings, the light shielding layer LS is connected to the drain electrode DE through the first contact hole CH1 passing through the buffer layer 111 and the gate insulating layer 112, and the fourth contact hole CH4 passing through the first insulating interlayer 113 and the second insulating interlayer 114, but not necessarily. The light shielding layer LS may be connected to the source electrode SE, but not limited thereto.

The second power line PL2 and first power line PL1 may be further disposed over the second insulating interlayer 114. The second power line PL2 is electrically connected to a first electrode of the light emitting diode LED together with the driving transistor T, and the first power line PL1 is connected to a second electrode of the light emitting diode LED, whereby the light emitting diode LED emits light. The second power line PL2 and the first power line PL1 may include a conductive material, for example, copper Cu, aluminum Al, molybdenum Mo, nickel Ni, titanium Ti, chromium Cr, or an alloy thereof, but not limited thereto.

A third insulating interlayer 115 may be provided over the source electrode SE and the drain electrode DE of the driving transistor T. The third insulating interlayer 115 may be provided to cover the driving transistor T. The third insulating interlayer 115 is an insulating layer for protecting configurations provided thereunder and may be composed of a single layer or multilayers of silicon oxide SiOx or silicon nitride SiNx, but not limited thereto.

A first planarization layer 116 may be provided over the third insulating interlayer 115. The first planarization layer 116 is provided to cover the driving transistor T, so that it is possible to protect the driving transistor, and to planarize a step difference caused by the driving transistor T. The first planarization layer 116 may be formed of an organic film such as acryl resin, epoxy resin, phenolic resin, polyamide resin, polyimide resin, etc.

A reflective electrode RE may be disposed over the first planarization layer 116 while being spaced apart from each other. The reflective electrode RE electrically connects the light emitting diode LED to the second power line PL2 or driving transistor T. At the same time, the reflective electrode RE may function as a reflective plate for reflecting light emitted from the light emitting diode LED to an upper portion of the light emitting diode LED. The reflective electrode RE is formed of a conductive material having the excellent reflective characteristics to reflect light emitted from the light emitting diode LED toward the upper portion of the light emitting diode LED. Accordingly, the light emitting diode display device 10 according to the present embodiment includes the reflective electrode RE so that the light emitting diode display device 10 according to the present disclosure may have a top emission structure.

The reflective electrode RE may include a first reflective electrode RE1 and a second reflective electrode RE2. The first reflective electrode RE1 may electrically connect the driving transistor T to the light emitting diode LED. The first reflective electrode RE1 may be connected to the source electrode SE or drain electrode DE of the driving transistor T through a contact hole formed in the first planarization layer 116. The first reflective electrode RE1 may be electrically connected to the first electrode 125 of the light emitting diode LED through the first connection electrode CE1.

The second reflective electrode RE2 may electrically connect the first power line PL1 and the light emitting diode LED to each other. The second reflective electrode RE2 may be connected to the first power line PL1 through a contact hole formed in the first planarization layer 116 and may be electrically connected to the second electrode 124 of the light emitting diode LED through the second connection electrode CE2.

A fourth insulating interlayer 117 may be provided over the reflective electrode RE. The fourth insulating interlayer 117 is an insulating layer for protecting configurations provided thereunder and may be composed of a single layer or multilayers of silicon oxide SiOx or silicon nitride SiNx, but not limited thereto.

An adhesive layer 118 may be disposed over the fourth insulating interlayer 117. The adhesive layer 118 is coated onto the entire surface of the first substrate 100 and is configured to fix the light emitting diode LED disposed over the adhesive layer 118. The position of the light emitting diode LED may be fixed by the adhesive layer 118. Material of the adhesive layer 118 may be selected from any one among adhesive copolymer, epoxy resist, UV resin, polyimide-based material, acrylate-based material, urethane-based material, and polydimethylsiloxane PDMS, but not limited thereto.

The light emitting diode LED may be provided over the adhesive layer 118. The light emitting diode LED is electrically connected to the driving transistor T and the first power line PL1, whereby the light emitting diode LED may emit light by a current flowing from the driving transistor T to the first power line PL1.

The light emitting diode LED may be provided in each light emitting area EA1, EA2, and EA3 of the subpixels SP1, SP2, and SP3. In detail, as shown in FIG. 2, the light emitting diode LED may include a first light emitting diode 120 provided in a first light emitting area EA1 of the first subpixel SP1, a second light emitting diode 130 provided in a second light emitting area EA2 of the second subpixel SP2, and a third light emitting diode 140 provided in a third light emitting area EA3 of the third subpixel SP3. For example, the first light emitting diode 120 may be a red light emitting diode, the second light emitting diode 130 may be a green light emitting diode, and the third light emitting diode 140 may be a blue light emitting diode. The unit pixel UP may further include a white subpixel. In this case, the light emitting diode LED may further include a white light emitting diode provided in a white subpixel.

Herein, one or more light emitting diodes LEDs may be provided in each of the first subpixel SP1, the second subpixel SP2, and the third subpixel SP3. For example, the unit pixel UP may include two first subpixels SP1a and SP1b, two second subpixels SP2a and SP2b, and two third subpixels SP3a and SP3b. In each of the two first subpixels SP1a and SP1b, there may be one pixel circuit and one first light emitting diode 120, but not limited thereto. The first light emitting diodes 120 respectively provided in the two first subpixels SP1a and SP1b may share one pixel circuit. Also, one pixel circuit and one second light emitting diode 130 may be provided in each of the two second subpixels SP2a and SP2b, but not limited thereto. The second light emitting diodes 130 respectively provided in the two second subpixels SP2a and SP2b may share one pixel circuit. Also, one pixel circuit and one third light emitting diode 140 may be provided in each of the two third subpixels SP3a and SP3b, but not limited thereto. The third light emitting diodes 140 respectively provided in the two third subpixels SP3a and SP3b may share one pixel circuit.

The first light emitting diode 120 includes a first semiconductor layer 121, a light emitting layer 122, a second semiconductor layer 123, a first electrode 124, and a second electrode 125. In the same manner as the first light emitting diode 120, each of the second light emitting diode 130 and the third light emitting diode 140 includes a first semiconductor layer, a light emitting layer, a second semiconductor layer, a first electrode, and a second electrode. Herein, configurations provided in each of the second light emitting diode 130 and the third light emitting diode 140 are the same as those provided in the first light emitting diode 120, whereby a description thereof will be omitted.

The first semiconductor layer 121 provides electrons to the light emitting layer 122. In one embodiment of the present disclosure, the first semiconductor layer 121 may be a layer formed by doping a specific material with n-type impurities. For example, the first semiconductor layer 121 may be formed of an n-GaN-based semiconductor material, and the n-GaN-based semiconductor material may be GaN, AlGaN, InGaN, or AlInGaN. Herein, the impurities used for doping of the first semiconductor layer 121 may be Si, Ge, Se, Te, or C.

The second semiconductor layer 123 provides holes to the light emitting layer 122. In one embodiment of the present disclosure, the second semiconductor layer 123 may be a layer formed by doping a specific material with p-type impurities. For example, the second semiconductor layer 123 may be formed of a p-GaN-based semiconductor material, and the p-GaN-based semiconductor material may be GaN, AlGaN, InGaN, or AlInGaN. Herein, the impurities used for doping of the second semiconductor layer 123 may be Mg, Zn, or Be.

The light emitting layer 122 may be provided between the first semiconductor layer 121 and the second semiconductor layer 123 on one side of the first semiconductor layer 121. The light emitting layer 122 may be supplied with electrons from the first semiconductor layer 121 and may be supplied with holes from the second semiconductor layer 123, thereby emit light. The light emitting layer 122 may have a multi-quantum well MQW structure having a well layer and a barrier layer, wherein a band gap of the barrier layer is higher than that of the well layer. In one embodiment of the present disclosure, the light emitting layer 122 may have a multiple quantum well structure, such as Indium Gallium Nitride InGaN or Gallium Nitride GaN.

The first electrode 124 is provided over the second semiconductor layer 123 and may be electrically connected to the source electrode SE or drain electrode DE of the driving transistor T. The first electrode 124 may correspond to an anode terminal.

The second electrode 125 may be provided over the other side of the first semiconductor layer 121, whereby the second electrode 125 may be electrically separated from the light emitting layer 122 and the second semiconductor layer 123. The second electrode 125 may be electrically connected to the first power line PL1. The second electrode 125 may correspond to a cathode terminal.

The first electrode 124 and the second electrode 125 may include a conductive material, for example, a transparent conductive material such as Indium Tin Oxide ITO or Indium Zinc Oxide IZO, or an opaque conductive material such as titanium Ti, gold Au, silver Ag, copper Cu, or an alloy thereof, but not limited to these materials.

The light emitting diode LED may emit light by re-bond of the electrons and holes according to a current flowing between the first electrode 124 and the second electrode 125. The light generated from the light emitting diode LED passes through each of the first electrode 124 and the second electrode 125 and emits to the outside, thereby displaying an image.

A second planarization layer 119 may be provided over the adhesive layer 118. The second planarization layer 119 may be provided to cover a portion of a side surface of the light emitting diode LED.

A third planarization layer 126 may be provided over the second planarization layer 119. The third planarization layer 126 may be provided to cover a portion of the side surface and an upper surface of the light emitting diode LED. The third planarization layer 126 may be provided only in a region adjacent to the light emitting diode LED, but not limited thereto.

The second planarization layer 119 and the third planarization layer 126 are disposed to cover at least partially the light emitting diode LED so that it is possible to fix and protect the light emitting diode LED and to planarize a step difference caused by the light emitting diode LED. The second planarization layer 119 and the third planarization layer 126 may be formed of an organic film such as acryl resin, epoxy resin, phenolic resin, polyamide resin, and polyimide resin.

The first connection electrode CE1 and second connection electrode CE2 may be provided over the second planarization layer 119 and the third planarization layer 126. The first connection electrode CE1 is provided over the second planarization layer 119 and the third planarization layer 126 to electrically connect the first electrode 124 of the light emitting diode LED and the source electrode SE or the drain electrode DE of the driving transistor T. The first connection electrode CE1 may be an anode electrode.

In detail, one side of the first connection electrode CE1 may be connected to the first reflective electrode RE1 through a fifth contact hole CH5 formed in the fourth insulating interlayer 117, the adhesive layer 118, the second planarization layer 119, and the third planarization layer 126. The first connection electrode CE1 may be electrically connected to the source electrode SE or drain electrode DE of the driving transistor T through the first reflective electrode RE1. The other side of the first connection electrode CE1 may be electrically connected to the first electrode 124 of the light emitting diode LED through a seventh contact hole CH7 provided in the third planarization layer 126. Accordingly, the first electrode 124 of the light emitting diode LED may be electrically connected to the source electrode SE or drain electrode DE of the driving transistor T through the first connection electrode CE1.

The first connection electrode CE1 may be formed of a transparent conductive material. The transparent conductive material may be Indium Tin Oxide ITO or Indium Zinc Oxide IZO, but not limited thereto.

The second connection electrode CE2 may be provided over the second planarization layer 119 and the third planarization layer 126 to electrically connect the second electrode 125 of the light emitting diode LED and the first power line PL1. The second connection electrode CE2 may be a cathode electrode.

In detail, one side of the second connection electrode CE2 may be connected to the second reflective electrode RE2 through a sixth contact hole CH6 passing through the fourth insulating interlayer 117, the adhesive layer 118, the second planarization layer 119, and the third planarization layer 126. The second connection electrode CE2 may be electrically connected to the first power line PL1 through the second reflective electrode RE2. The other side of the second connection electrode CE2 may be electrically connected to the second electrode 125 of the light emitting diode LED through an eighth contact hole CH8 provided in the third planarization layer 126. Accordingly, the second electrode 125 of the light emitting diode LED may be electrically connected to the first power line PL1 through the second connection electrode CE2. The second connection electrode CE2 may be formed of the same material as the first connection electrode CE1.

In one embodiment of the present disclosure, the light emitting diode display device 10 may further include a bank 210. The bank 210 may be provided over the third planarization layer 126 and may be configured to cover at least a portion of the first connection electrode CE1 and at least a portion of the second connection electrode CE2. The bank 210 may be provided to fill the fifth contact hole CH5 on the first connection electrode CE1 provided in the fifth contact hole CH5. Also, the bank 210 may be provided to fill the sixth contact hole CH6 on the second connection electrode CE2 provided in the sixth contact hole CH6.

The bank 210 may define the light emitting areas EA1, EA2, and EA3 of each of the subpixels SP1, SP2, and SP3. The bank 210 may include a first opening area OA1 corresponding to the light emitting area EA1, EA2, and EA3 through which light emitted from the light emitting diode LED is emitted to the outside. The light emitted from the light emitting diode LED provided in each of the subpixels SP1, SP2, and SP3 may be emitted to the outside from the first opening area OA1 of the bank 210. Accordingly, the light emitting areas EA1, EA2, and EA3 of each of the subpixelsSP1, SP2, and SP3 may correspond to the region in which the bank 210 is not formed.

Meanwhile, the bank 210 may be formed of an organic film such as acryl resin, epoxy resin, phenolic resin, polyamide resin, polyimide resin, etc. The bank 210 may include a black material for absorbing light. Accordingly, the light emitted from the light emitting diode LED provided in each of the subpixels SP1, SP2, and SP3 may be absorbed in the region in which the bank 210 is formed and may not be emitted to the outside. Accordingly, the region in which the bank 210 is formed may correspond to a non-light emitting area NEA. The bank 210 prevents or at least reduces the light emitted from the light emitting diode LED from proceeding to the adjacent subpixel SP1, SP2, and SP3, thereby preventing or at least reducing color mixing between the subpixels SP1, SP2, and SP3

A fourth planarization layer 220 may be provided over the bank 210 and the first and second connection electrodes CE1 and CE2. The fourth planarization layer 220 may be provided to cover a portion of the first connection electrode CE1 and a portion of the second connection electrode CE2 exposed without being covered by the upper surface of the bank 210 and to cover the bank 210. The fourth planarization layer 220 may provide a flat surface on the bank 210. The fourth planarization layer 220 may be formed of a single layer or a plurality of layers. For example, the fourth planarization layer 220 may include a first organic layer 222 and a second organic layer 224. The first organic layer 222 covers a step difference between the bank 210 and the first connection electrode CE1 and the second connection electrode CE2, thereby provide a flat surface. The second organic layer 224 is provided over the first organic layer 222 and is configured to secure an optical distance between the light emitting diode LED and the lens 230.

The fourth planarization layer 220 may be formed of an organic film such as acryl resin, epoxy resin, phenolic resin, polyamide resin, and polyimide resin. When the fourth planarization layer 220 includes the first organic layer 222 and the second organic layer 224, the first organic layer 222 and the second organic layer 224 may be formed of different materials. The first organic layer 222 and the second organic layer 224 may have different refractive indices, but not limited thereto. The first organic layer 222 and the second organic layer 224 may have the same refractive index.

The lens 230 may be convex toward the second substrate 300 on the fourth planarization layer 220. The lens 230 may be provided in each of light emitting areas EA1, EA2, and EA3 for each of the subpixels SP1, SP2, and SP3. That is, the lens 230 may be disposed in the first opening area OA1 of the bank 210. Also, the lens 230 may be provided to overlap the light emitting diode LED provided in each of the subpixels SP1, SP2, and SP3. As shown in FIGS. 2 and 3, the lens 230 may be disposed to correspond to the light emitting areas EA1, EA2, and EA3 in a one-to-one correspondence, but not limited thereto. The lens 230 may be disposed to correspond to the light emitting diode LED in a one-to-one correspondence, but not necessarily limited thereto.

The lens 230 is provided over the light emitting diode LED and is configured to change a path of light to be close to the front surface by refracting the light emitted from the light emitting diode LED. Herein, the front surface may indicate a position where a viewing angle is 0°.

The light generated by the light emitting diode LED may have a luminance distribution of ‘M’ shape having a maximum (or increased) luminance at a viewing angle greater than 0°. For example, the light generated from the light emitting diode LED may have a maximum (or increased) luminance at a viewing angle of 60°. Thus, the luminance distribution of ‘M’ shape is inefficient because the luminance at the front surface (0°) is low. According to one embodiment of the present disclosure, the light emitting diode display device 10 includes the lens 230 and the scattering pattern 240 above the light emitting diode LED so that it is possible to improve the luminance at the front surface (0°) by changing a path of light emitted from the light emitting diode LED.

In detail, the lens 230 may partially change the light emitted from the light emitting diode LED. The light generated from the light emitting diode LED may pass through the fourth planarization layer 220, and a portion of the transmitted light may be incident on the lens 230. The lens 230 may collect the incident light and send the collected light to the outside.

The lens 230 may include a flat surface 230a and a curved surface 230b. The flat surface 230a of the lens 230 faces the light emitting diode LED and may be in contact with the upper surface of the fourth planarization layer 220. The curved surface 230b of the lens 230 may be convex toward the second substrate 300.

A part of the light transmitted through the fourth planarization layer 220 may be incident on the flat surface 230a of the lens 230, as shown in FIG. 4. The light L1 incident on the flat surface 230a of the lens 230 is refracted and proceeds to the curved surface 230b of the lens 230, and then may be refracted again on the curved surface 230b of the lens 230. The refracted light L1 may pass through the fifth planarization layer 250 and the second substrate 300 and may emit to the outside. In the light emitting diode display device 10 according to one embodiment of the present disclosure, the light L1 incident on the lens 230 is refracted in the direction close to the front surface (0°) on the flat surface 230a and the curved surface 230b of the lens 230, to thereby improve the luminance at the front surface (0°).

This lens 230 may include an organic material having a first refractive index. The first refractive index may be greater than 1.5 and may be 1.6 or greater. Hereinafter, the lens 230 having the first refractive index is referred to as a high refractive lens. The high refractive lens 230 may have a refractive index different from that of the fourth planarization layer 220, but not necessarily limited thereto. The high refractive lens 230 may have the same refractive index as that of the fourth planarization layer 220.

Together with the high refractive lens 230, the scattering pattern 240 may be provided in each light emitting area EA1, EA2, and EA3 for each of the subpixels SP1, SP2, and SP3. That is, the scattering pattern 240 may be disposed in the first opening area OA1 of the bank 210. Unlike the high refractive lens 230, the scattering pattern 240 may not overlap the light emitting diode LED provided in each of the subpixels SP1, SP2, and SP3.

As shown in FIGS. 2 and 3, the scattering pattern 240 may be disposed to correspond to the light emitting areas EA1, EA2, and EA3 in a one-to-one correspondence, but not necessarily limited thereto. The scattering patterns 240 provided in the light emitting areas EA1, EA2, and EA3 of the subpixels SP1, SP2, and SP3 may be formed in one pattern connected to each other. If the scattering patterns 240 are formed in one pattern, the light emitted from the light emitting diode LED may be scattered and proceed to the neighboring subpixels SP1, SP2, and SP3, whereby the color mixing may occur between the neighboring subpixels SP1, SP2, and SP3.

The scattering patterns 240 provided in the light emitting areas EA1, EA2, and EA3 of the subpixels SP1, SP2, and SP3 are spaced apart from each other, thereby preventing or at least reducing the color mixing between the neighboring subpixels SP1, SP2, and SP3. In this case, each of the scattering patterns 240 may have a circular-shaped edge as shown in FIG. 2, but not limited thereto. Each of the scattering patterns 240 may have a rectangular-shaped edge as shown in FIG. 8.

The scattering pattern 240 is provided over the light emitting diode LED and is configured to scatter the light emitted from the light emitting diode LED and to change a path of the light so that the light may proceed close to the front surface.

Specifically, the scattering pattern 240 may include a lower surface 240a, an upper surface 240b, a first side surface 240c, and a second side surface 240d. The scattering pattern 240 is provided over the fourth planarization layer 220 so that the lower surface 240a may be in contact with the fourth planarization layer 220. The lower surface 240a of the scattering pattern 240 may be disposed over the same plane as the flat surface 230a of the high refractive lens 230.

The scattering pattern 240 may be provided over the curved surface 230b of the high refractive lens 230 and may include a second opening area OA2 exposing at least a portion of the curved surface 230b of the high refractive lens 230. The second opening area OA2 of the scattering pattern 240 may expose a portion of the curved surface 230b of the high refractive lens 230, which overlaps the light emitting diode LED. Thus, a region in which the light emitting diode LED is provided may be disposed in the second opening area OA2 of the scattering pattern 240. The second opening area OA2 of the scattering pattern 240 may have a circular shape as shown in FIG. 2, but not limited thereto.

The scattering pattern 240 may have a thickness Ts which is lower than a height H of the high refractive lens 230. Accordingly, the upper surface 240b of the scattering pattern 240, which faces the second substrate 300, may be in contact with the fifth planarization layer 250, and the first side surface 240c of the scattering pattern 240, which faces the curved surface 230b of the high refractive lens 230, may be in contact with the curved surface 230b of the high refractive lens 230. Also, the second side surface 240d of the scattering pattern 240, which faces the neighboring subpixels SP1, SP2, and SP3 may be in contact with the fifth planarization layer 250.

This scattering pattern 240 may be formed over the high refractive lens 230 after the high refractive lens 230 is formed. More specifically, the high refractive lens 230 may be formed over the first substrate 100 on which the fourth planarization layer 220 is formed through a photolithography process. Then, the scattering pattern 240 including scattering particles 241 may be formed on the first substrate 100 on which the high refractive lens 230 is formed through an inkjet coating or photolithography process.

A part of the light transmitted through the fourth planarization layer 220 may be incident on the lower surface 240a of the scattering pattern 240, as shown in FIG. 4. The light L2 incident on the lower surface 240a of the scattering pattern 240 may be refracted and scattered in the scattering pattern 240. The refracted and scattered light L2 may pass through the fifth planarization layer 250 and the second substrate 300 and may be emitted to the outside. In the light emitting diode display device 10 according to one embodiment of the present disclosure, the light L2 incident on the scattering pattern 240 is refracted and scattered on the scattering pattern 240 to the direction of the front surface (0°) so that it is possible to improve the luminance at the front surface (0°).

The scattering pattern 240 may include an organic material having a second refractive index and a plurality of scattering particles 241. The second refractive index may be less than 1.6, or less than 1.5, and may be smaller than the first refractive index. The organic material of the scattering pattern 240 may have the same refractive index as that of the fourth planarization layer 220, but not limited thereto. The organic material of the scattering pattern 240 may have a refractive index which is different from that of the fourth planarization layer 220.

The fifth planarization layer 250 may be provided over the high refractive lens 20 and may be configured to cover the high refractive lens 230. The fifth planarization layer 250 may be provided to cover the curved surface 230b of the high refractive lens 230 exposed by the second opening area OA2 of the scattering pattern 240. Accordingly, the high refractive lens 230 may be in contact with the fifth planarization layer 250 at the curved surface 230b exposed by the second opening area OA2 of the scattering pattern 240.

Meanwhile, the fifth planarization layer 250 may be provided over the scattering pattern 240 and may be configured to cover the scattering pattern 240. The fifth planarization layer 250 may be provided between the scattering patterns 240 provided in the light emitting areas EA1, EA2, and EA3 of the subpixels SP1, SP2, and SP3. That is, the fifth planarization layer 250 may be provided to cover the upper surface 240b and the second side surface 240d of the scattering pattern 240. Accordingly, the scattering pattern 240 may be in contact with the fifth planarization layer 250 on its upper surface 240b and second side surface 240d.

The fifth planarization layer 250 may planarize the step difference generated by the high refractive lens 230 and the scattering pattern 240. The fifth planarization layer 250 may be formed of an organic material having a refractive index which is lower than that of the high refractive lens 230. That is, the fifth planarization layer 250 may have a third refractive index which is smaller than the first refractive index. The third refractive index may be equal to or less than 1.5 and may be between 1.4 and 1.5. Hereinafter, the fifth planarization layer 250 having the third refractive index is referred to as a low refractive planarization layer.

The second substrate 300 is disposed to cover a portion of the first substrate 100 except a pad portion, to thereby protect a pixel array provided over the first substrate 100. The second substrate 300 may be defined as an opposite substrate, an encapsulation substrate, or a color filter array substrate, and may be bonded to the first substrate 100 through an adhesive layer (not shown). The second substrate 300 may be formed of a transparent glass material or a transparent plastic material, but not limited thereto.

In the light emitting diode display device 10 according to one embodiment of the present disclosure, the high refractive lens 230 and the scattering pattern 240 are provided over the light emitting diode LED so that it is possible to change the path of light emitted from the light emitting diode LED, thereby improving the luminance at the front surface (0°) and improving the luminance distribution for each inefficient viewing angle of the light emitting diode LED.

Specifically, the light emitting diode display device 10 according to one embodiment of the present disclosure may change the path of light having a small angle among the light emitted from the light emitting diode LED by using the high refractive lens 230 provided over the light emitting diode LED. The first light L1 having an angle less than or equal to a reference angle of the light emitted from the light emitting diode LED may be incident on the high refractive lens 230, as shown in FIG. 4. The first light L1 may be refracted by the high refractive lens 230 and may be emitted to the outside. In the light emitting diode display device 10 according to one embodiment of the present disclosure, the first light L1 is refracted to the direction of the front surface (0°) by the high refractive lens 230, to thereby improve the luminance at the front surface (0°).

The light having a large angle among the light emitted from the light emitting diode LED may not be incident to the high refractive lens 230. When the scattering pattern 240 is not provided in the light emitting diode display device 10, the light having a large angle is not refracted by the high refractive lens 230 and is transmitted to the low refractive planarization layer 250 and the second substrate 300 as it is, or a total reflection may occur in the low refractive planarization layer 250, whereby the light is not emitted to the outside. Accordingly, the light emitting diode display device 10 has a limitation in front (0°) luminance and light extraction efficiency.

The light emitting diode display device 10 according to one embodiment of the present disclosure may change the path of light having a large angle among the light emitted from the light emitting diode LED by using the scattering pattern 240 provided on the light emitting diode LED. The second light L2 having an angle greater than the reference angle of the light emitted from the light emitting diode LED may be incident on the scattering pattern 240, as shown in FIG. 4. The second light L2 may be refracted and scattered by the scattering pattern 240, whereby the light may be emitted to the outside. In the light emitting diode display device 10 according to one embodiment of the present disclosure, the second light L2 may be refracted and scattered in the direction close to the front surface (0°) by the scattering pattern 240 so that it is possible to further improve the luminance at the front surface (0°).

As described above, the light emitting diode display device 10 according to one embodiment of the present disclosure includes the high refractive lens 230 and the scattering pattern 240 over the light emitting diode LED, whereby the light emitted from the light emitting diode LED, that is, the light having the large angle as well as the light having the small angle may be refracted in the direction close to the front surface (0°). Accordingly, the light emitting diode display device 10 according to one embodiment of the present disclosure greatly improves the luminance at the front surface (0°) and prevents (or at least reduce) the total reflection from occurring in the low refractive planarization layer 250, at the same time, thereby improving the light extraction efficiency.

The light emitting diode display device 10 according to one embodiment of the present disclosure includes the fourth planarization layer 220 between the light emitting diode LED and the high refractive lens 230 so that it is possible to secure an optical distance between the light emitting diode LED and the high refractive lens 230, thereby increasing the light collecting effect of the high refractive lens 230.

In detail, the thickness ‘Tp’ of the fourth planarization layer 220 may be determined based on the radius ‘r’ of the high refractive lens 230 and the length ‘d’ of the light emitting diode LED. In the light emitting diode display device 10 according to one embodiment of the present disclosure, the first light L1 having an angle which is smaller than or equal to the reference angle among the light emitted from the light emitting diode LED is incident on the high refractive lens 230 and the second light L2 having the angle which is larger than the reference angle is incident on the scattering pattern 240 so that it is possible to realize the maximum light extraction efficiency or at least increase light extraction efficiency. In this case, the reference angle may be an angle between 400 and 50°. For example, the reference angle may be 45°.

In order to satisfy the conditions for the maximum light extraction efficiency or increased light extraction efficiency described above, the minimum angle of the light incident on the lower surface 240a of the scattering pattern 240 from the light emitting diode LED is greater than the reference angle. That is, as shown in FIG. 5, a first angle θi between a straight line L1 perpendicular to the first substrate 100 and a straight line L2 passing through one end of the high refractive lens 230 from one end of the light emitting layer 123 of the light emitting diode 120 in the shortest distance is greater than the reference angle. Herein, one end of the light emitting layer 123 may indicate the end of the side facing the same direction.

When the center of the high refractive lens 230 and the center of the light emitting layer 123 of the light emitting diode 120 is on the same line L3, it is possible to satisfy the following Equation 1.

$$tan ( {θ}_{i} ) = \frac{{T}_{p}}{r - \frac{d}{2}} \qquad Equation 1$$

Herein, ‘θi’ denotes the first angle, ‘Tp’ denotes the thickness of the fourth planarization layer 220, ‘r’ denotes the radius of the high refractive lens 230, and ‘d’ denotes the length of the light emitting diode LED, and more particularly, the length of the light emitting layer 123.

Since the first angle ‘θi’ is greater than 45°, tan ‘θi’ may be greater than 1. Accordingly, the thickness ‘Tp’ of the fourth planarization layer 220 may satisfy the following Equation 2.

$${T}_{p} > r - \frac{d}{2} \qquad Equation 2$$

In the light emitting diode display device 10 according to one embodiment of the present disclosure, the fourth planarization layer 220 has the thickness ‘Tp’ satisfying the above Equation 2 so that it is possible to maximize or at least increase the luminance at the front surface (0°) and the light extraction efficiency.

Also, in the light emitting diode display device 10 according to one embodiment of the present disclosure, the thickness ‘Ts’ of the scattering pattern 240 is lower than the height ‘H’ of the high refractive lens 230. Accordingly, the high refractive lens 230 may be formed such that a portion of the curved surface 230b is exposed and the exposed curved surface 230b is in contact with the low refractive planarization layer 250. A portion of the first light L1 passing through the high refractive lens 230 may be directly incident on the low refractive planarization layer 250 and may be emitted to the outside through the low refractive planarization layer 250 and the second substrate 300. On the other hand, another portion of the first light L1 passing through the high refractive lens 230 is incident on the scattering pattern 240 and is scattered and refracted by the scattering pattern 240, whereby it proceeds to the low refractive planarization layer 250.

The light emitting diode display device 10 according to one embodiment of the present disclosure adjusts the thickness ‘Ts’ of the scattering pattern 240 so that it is possible to prevent or at least reduce the light directly incident from the high refractive lens 230 to the low refractive planarization layer 250 from being totally reflected on the low refractive planarization layer 250.

The light emitting diode display device 10 according to one embodiment of the present disclosure may adjust the thickness ‘Ts’ of the scattering pattern 240 in consideration of the path of light passing through the region where the curved surface 230b of the high refractive lens 230 meets the upper surface 240b of the scattering pattern 240.

In one embodiment of the present disclosure, the scattering pattern 240 may have the thickness ‘Ts’ satisfying the following Equation 3.

$${θ}_{out} < about {44}^{∘} \qquad Equation 3$$

Herein, as shown in FIG. 6, ‘θout’ may indicate the second angle between the light transmitted to the low refractive planarization layer 250 and a straight line L4 perpendicular to the first substrate 100 or a normal line of the light emitting diode LED at a point where the curved surface 230b of the high refractive lens 230 meets the upper surface 240b of the scattering pattern 240. The above Equation 3 may be derived by the following Equation 4 according to the Snell's law.

$${n}_{low} \times sin ( {θ}_{out} ) < {n}_{a i r} \times sin ( 90 ) \qquad Equation 4$$

Herein, ‘nlow’ represents a refractive index of the low refractive planarization layer 250, ‘θout’ represents the second angle, and ‘nair’ represents a refractive index of air. In the above Equation 3, the value ‘44’ may be changed according to the refractive index of the low refractive planarization layer 250.

In one embodiment of the present disclosure, the scattering pattern 240 may have the thickness ‘Ts’ satisfying the following Equation 5.

$$sin ( \frac{{n}_{low}}{{n}_{high}} sin ( {θ}_{out} - atan ( \frac{R - α}{\sqrt{2 R α - {α}^{2}}} ) ) ) + atan ( \frac{R - α}{\sqrt{2 R α - {α}^{2}}} ) = asin ( \frac{{n}_{p}}{{n}_{high}} sin ( atan ( \frac{\sqrt{2 R α - {α}^{2}} + d / 2}{R - α + {T}_{p}} ) ) ) \qquad Equation 5$$

Herein, ‘nlow’ represents the refractive index of the low refractive planarization layer 250, ‘θout’ represents the second angle, ‘nhigh’ represents the refractive index of the high refractive lens 230, and ‘R’ represents the radius of curvature of the high refractive lens 230. Also, ‘u’ may represent a difference between the height ‘H’ of the high refractive lens 230 and the thickness ‘Ts’ of the scattering pattern 240. Also, ‘np’ represents the refractive index of the fourth planarization layer 220, ‘Tp’ represents the thickness of the fourth planarization layer 220, and ‘d’ represents the length of the light emitting diode LED. The length of the light emitting diode LED may indicate the length of the light emitting layer 123, but not necessarily limited thereto. The length of the light emitting diode LED may indicate a long side length of a chip having the light emitting diode LED.

The above Equation 5 may be derived by the following Equation 6, Equation 7, Equation 8, and Equation 9 according to the Snell's law.

$${θ}_{high} = sin ( \frac{{n}_{low}}{{n}_{high}} sin ( {θ}_{low} ) ) = sin ( \frac{{n}_{low}}{{n}_{high}} sin ( {θ}_{out} - atan ( \frac{R - α}{\sqrt{2 R α - {α}^{2}}} ) ) ) \qquad Equation 6$$

Herein, ‘θhigh’ may indicate a third angle obtained between the light transmitted from the high refractive lens 230 and a normal line L6 of the high refractive lens 230 at a point where the curved surface 230b of the high refractive lens 230 meets the upper surface 240b of the scattering pattern 240. Also, ‘θlow’ may indicate a fourth angle obtained between the light transmitted to the low refractive planarization layer 250 and the normal line L6 of the high refractive lens 230 at the point where the curved surface 230b of the high refractive lens 230 meets the upper surface 240b of the scattering pattern 240. Herein, ‘nlow’ represents the refractive index of the low refractive planarization layer 250, ‘nhigh’ represents the refractive index of the high refractive lens 230, and ‘α’ may represent a difference between the height ‘H’ of the high refractive lens 230 and the thickness ‘Ts’ of the scattering pattern 240.

$${θ}_{i n} = sin ( \frac{{n}_{low}}{{n}_{high}} sin ( {θ}_{out} - atan ( \frac{R - α}{\sqrt{2 R α - {α}^{2}}} ) ) ) + atan ( \frac{R - α}{\sqrt{2 R α - {α}^{2}}} ) \qquad Equation 7$$

Herein, ‘θin’ may represent a fifth angle obtained between the light transmitted from the high refractive lens 230 and the straight line L4 perpendicular to the first substrate 100 or the normal line of the light emitting diode LED at the point where the curved surface 230b of the high refractive lens 230 meets the upper surface 240b of the scattering pattern 240. The fifth angle ‘θin’ may correspond to a value obtained by adding the third angle ‘θhigh’ to the difference between the second angle ‘θout’ and the fourth angle ‘θlow’. Accordingly, the Equation 7 may be derived by adding the difference between the second angle ‘θout’ and the fourth angle ‘θlow’ to the Equation 6.

$${θ}_{p} = atan ( \frac{\sqrt{2 R α - {α}^{2}} + d / 2}{R - α + {T}_{p}} ) \qquad Equation 8$$

Herein, ‘θp’ may indicate a sixth angle obtained between the light transmitted from the fourth planarization layer 220 and the straight line L4 perpendicular to the first substrate 100 or the normal line of the light emitting diode LED. Also, ‘a’ may represent the difference between the height ‘H’ of the high refractive lens 230 and the thickness ‘Ts’ of the scattering pattern 240. Also, ‘Tp’ represents the thickness of the fourth planarization layer 220, and ‘d’ represents the length of the light emitting diode LED. The length of the light emitting diode LED may indicate the length of the light emitting layer 123, but not necessarily limited thereto. The length of the light emitting diode LED may indicate the long side length of the chip having the light emitting diode LED. Since the sixth angle ‘θp’ and the fifth angle ‘θin’ satisfy the Snell's law, the Equation 9 may be derived.

$${θ}_{i n} = asin ( \frac{{n}_{p}}{{n}_{high}} sin ( atan ( \frac{\sqrt{2 R α - {α}^{2}} + d / 2}{R - α + {T}_{p}} ) ) ) \qquad Equation 9$$

As a result, the above Equation 5 may be derived by the Equation 7 and Equation 9.

In one embodiment of the present disclosure, the scattering pattern 240 may have the thickness ‘Ts’ satisfying the Equation 4 and Equation 5.

Hereinafter, the thickness ‘Ts’ of the scattering pattern 240 will be described with reference to the simulation input condition shown in FIGS. 7A and 7B and the result of simulating the change in the second angle ‘θout’ for each thickness ‘Ts’ of the scattering pattern 240 according to the simulation input condition.

Referring to FIG. 7A, the simulation input conditions may correspond to the thickness ‘Tp’ and refractive index of the fourth planarization layer 220, the refractive index and height ‘H’ of the high refractive lens 230, the refractive index of the low refractive planarization layer 250, and the length ‘d’ of the light emitting diode LED. For example, the fourth planarization layer 220 may have the thickness ‘Tp’ of 15 μm and the refractive index of 1.53 under the simulation input conditions. The high refractive lens 230 may have the refractive index of 1.64 and the height of 6 μm. The low refractive planarization layer 250 may have the refractive index of 1.44. The light emitting diode LED may have the length ‘d’ of 16 μm.

As a result of simulation according to the simulation input conditions, the change in the second angle ‘θout’ for each thickness ‘Ts’ of the scattering pattern 240 is shown in FIG. 7B. Referring to FIG. 7B, the second angle obtained between the light transmitted to the low refractive planarization layer 250 and the straight line L4 perpendicular to the first substrate 100 or the normal line of the light emitting diode LED at the point where the curved surface 230b of the high refractive lens 230 meets the upper surface 240b of the scattering pattern 240 may be increased according to the decrease in thickness ‘Ts’ of the scattering pattern 240. Meanwhile, in order to prevent the light directly incident from the high refractive lens 230 to the low refractive planarization layer 250 from being totally reflected in the low refractive planarization layer 250, the second angle ‘θout’ should be maintained to be less than about 440 according to the above Equation 4 and Equation 3. Accordingly, according to the simulation result shown in FIG. 7B, the scattering pattern 240 may be designed to have the thickness ‘Ts’ of 5 μm or more so that the second angle ‘θout’ has a value smaller than about 44°.

In the light emitting diode display device 10 according to one embodiment of the present disclosure, the thickness ‘Ts’ of the scattering pattern 240 is designed to satisfy the condition for preventing or at least reducing the light directly incident from the high refractive lens 230 to the low refractive planarization layer 250 from being totally reflected in the low refractive planarization layer 250. That is, the light emitting diode display device 10 according to one embodiment of the present disclosure may not have the scattering pattern 240 in the region satisfying the condition in which the total reflection does not occur in the low refractive planarization layer 250 when the light is directly incident from the high refractive lens 230 to the low refractive planarization layer 250. Accordingly, the light emitting diode display device 10 according to one embodiment of the present disclosure may expect a high light collection effect by the high refractive lens 230 in the region satisfying the condition in which the total reflection does not occur in the low refractive planarization layer 250.

On the other hand, the light emitting diode display device 10 according to one embodiment of the present disclosure may have the scattering pattern 240 in a region where the total reflection occurs in the low refractive planarization layer 250 when the light is directly incident from the high refractive lens 230 to the low refractive planarization layer 250. Accordingly, the light emitting diode display device 10 according to one embodiment of the present disclosure may be provided so that a portion of the curved surface 230b of the high refractive lens 230 is in contact with the scattering pattern 240. A part of the light incident on the high refractive lens 230 may be incident on the scattering pattern 240 from the high refractive lens 230. The light incident from the high refractive lens 230 to the scattering pattern 240 may be scattered and refracted by the plurality of scattering particles 241 and may proceed to the low refractive planarization layer 250.

As described above, the light emitting diode display device 10 according to one embodiment of the present disclosure changes the path of light by the scattering pattern 240 and then makes the light be incident on the low refractive planarization layer 250 so that it is possible to minimize or at least reduce the total reflection in the low refractive planarization layer 250, thereby improving the light extraction efficiency.

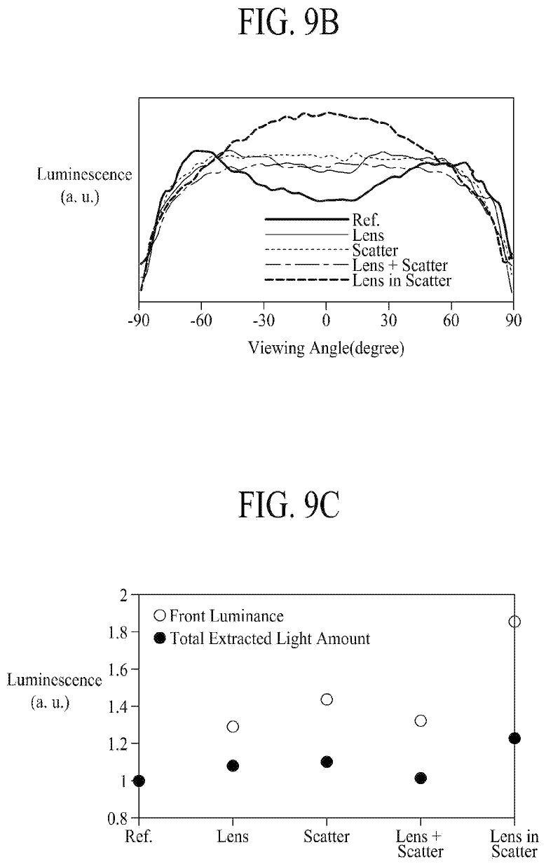

FIG. 9A is a table indicating simulation input conditions, FIG. 9B shows a result of simulating changes in luminance for each viewing angle with respect to various embodiments according to the simulation input conditions shown in FIG. 9A, and FIG. 9C is a diagram illustrating a result of simulating front luminance and total extracted light amount for various embodiments according to the simulation input conditions shown in FIG. 9A.

Referring to FIG. 9A, the simulation input conditions may include a diameter, mass fraction and refractive index of the scattering particles 241 included in the scattering pattern 240, a refractive index and thickness of the medium into which the scattering particles 241 are injected, and a refractive index and thickness of the high refractive lens 230. For example, under the simulation input conditions, the scattering particles 241 included in the scattering pattern 240 may have a diameter of 200 nm, a mass fraction of 6 wt %, and a refractive index of 2.3. The medium into which the scattering particles 241 are injected may have a refractive index of 1.44 and a thickness of 6 μm. The high refractive lens 230 may have a refractive index of 1.64 and a height of 6 μm.

A result of simulating changes in luminance for each viewing angle with respect to various embodiments according to the simulation input conditions is shown in FIG. 9B. Also, a result of simulating front luminance and total extracted light amount for various embodiments according to the simulation input conditions is shown in FIG. 9C.

Referring to FIGS. 9B and 9C, the first embodiment Ref. may be an example in which both the high refractive lens 230 and the scattering pattern 240 are not provided over the light emitting diode LED. The second embodiment Lens may be an example in which only the high refractive lens 230 is provided over the light emitting diode LED. The third embodiment Scatter may be an example in which only the scattering pattern 240 is provided over the light emitting diode LED. The fourth embodiment Lens+Scatter may be an example in which the high refractive lens 230 and the scattering pattern 240 are provided over the light emitting diode LED. Herein, the scattering pattern 240 may be provided over the high refractive lens 230 and may be configured to overlap the high refractive lens 230.

The fifth embodiment Lens in Scatter may be another example in which the high refractive lens 230 and the scattering pattern 240 are provided over the light emitting diode LED. As shown in FIGS. 2 to 6, the fifth embodiment may include the high refractive lens 230 and the scattering pattern 240 provided on the same plane, and the second opening area OA2 exposing at least a portion of the curved surface 230b of the high refractive lens 230 may be provided in the scattering pattern 240.

In comparison to the first embodiment Ref., the fifth embodiment Lens in Scatter may have a front luminance increased by about 80% and a total extraction light intensity increased by about 20%. Also, in comparison to other embodiments in addition to the first embodiment Ref., the fifth embodiment Lens in Scatter may have higher front luminance and high total extraction light amount.

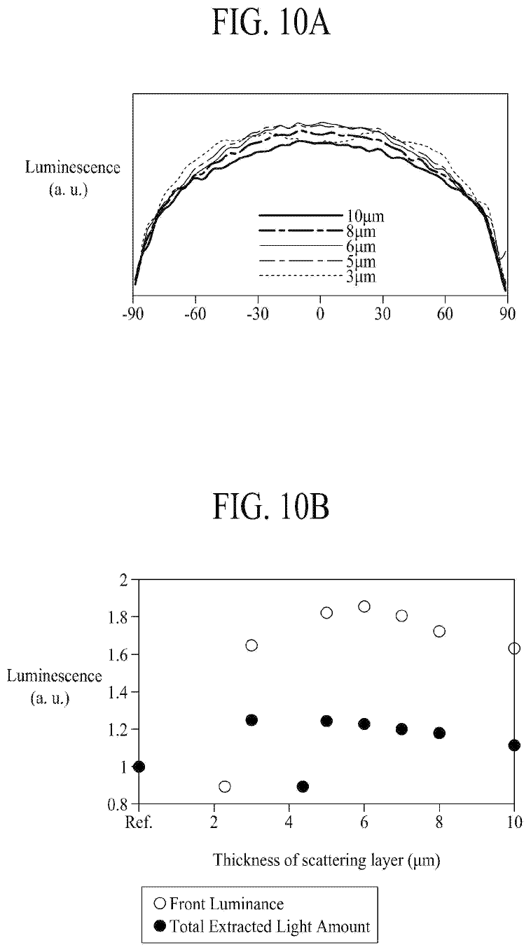

FIG. 10A illustrates a result of simulating a change in luminance for each viewing angle with respect to various thicknesses of the scattering pattern, and FIG. 10B illustrates a result of simulating front luminance and total extracted light amount with respect to various thicknesses of the scattering pattern.

Herein, simulation input conditions may include a diameter, mass fraction and refractive index of the scattering particles 241 included in the scattering pattern 240, a refractive index and thickness of the medium into which the scattering particles 241 are injected, and a refractive index and thickness of the high refractive lens 230, described with respect to the above FIG. 9A. For example, under the simulation input conditions, the scattering particles 241 included in the scattering pattern 240 may have a diameter of 200 nm, a mass fraction of 6 wt %, and a refractive index of 2.3. The medium into which the scattering particles 241 are injected may have a refractive index of 1.44. The high refractive lens 230 may have a refractive index of 1.64 and a height of 6 μm.

A result of simulating changes in luminance for each viewing angle with respect to various thicknesses of the scattering pattern according to the simulation input conditions is shown in FIG. 10A. A result of simulating the front luminance and total extracted light amount with respect to various thicknesses of the scattering pattern according to the simulation input conditions is shown in FIG. 10B.

Referring to FIGS. 10A and 10B, when the thickness of the scattering pattern 240 is 6 μm, the front luminance is the highest. When the thickness of the scattering pattern 240 is 7 μm or more, the light proceeding to the front surface by the high refractive lens 230 is scattered by the scattering pattern 240, whereby the front luminance is reduced. In addition, when the thickness of the scattering pattern 240 is less than 6 μm, the front luminance may be reduced due to the reduction of the scattering effect by the scattering pattern 240.

On the other hand, in comparison to the reference embodiment Ref. in which both the high refractive lens 230 and the scattering pattern 240 are not provided, the total extracted light amount is increased by about 20% regardless of the thickness of the scattering pattern 240.

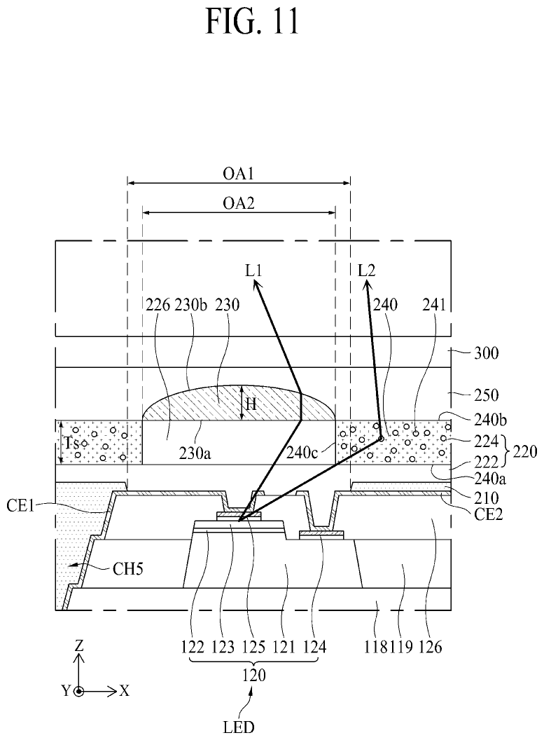

FIG. 11 is a cross sectional view along line I-I′ of FIG. 2.

The light emitting diode display device 10 according to another embodiment of the present disclosure may include a driving transistor T, a plurality of insulating layers, a light emitting diode LED, a first connection electrode CE1, a second connection electrode CE2, a high refractive lens 230, a scattering pattern 240, a low refractive planarization layer 250, and a second substrate 300 provided over a first substrate 100.

The light emitting diode display device 10 according to another embodiment of the present disclosure is substantially the same as the light emitting diode display device 10 according to one embodiment of the present disclosure shown in FIGS. 2 to 6, except for a fourth planarization layer 220, a high refractive lens 230, and a scattering pattern 240. Hereinafter, different configurations will be mainly described, and descriptions of substantially the same configurations will be omitted.

Referring to FIG. 11, a fourth planarization layer 220 may be provided on the bank 210 and the first and second connection electrodes CE1 and CE2. The fourth planarization layer 220 may be provided to cover a portion of the first connection electrode CE1 and a portion of the second connection electrode CE2 exposed without being covered by an upper surface of the bank 210 and the bank 210. The fourth planarization layer 220 may provide a flat surface on the bank 210. The fourth planarization layer 220 may include a single layer or a plurality of layers. For example, the fourth planarization layer 220 may include a first organic layer 222 and a second organic layer 224. The first organic layer 222 covers a step difference between the bank 210 and the first connection electrode CE1/the second connection electrode CE2, to thereby provide a flat surface. The second organic layer 224 is provided over the first organic layer 222, to thereby secure an optical distance between the light emitting diode LED and the high refractive lens 230.

The second organic layer 224 of the fourth planarization layer 220 may include an organic pattern 226 and a scattering pattern 240. The organic pattern 226 is provided in a region overlapped with the light emitting diode LED, and may not include scattering particles 241, unlike the scattering pattern 240. The scattering pattern 240 may be provided in a region which is not overlapped with the light emitting diode LED and may include a plurality of scattering particles 241.

The scattering pattern 240 may be provided in each light emitting area EA1, EA2, and EA3 of each of subpixels SP1, SP2, and SP3 together with the high refractive lens 230. That is, the scattering pattern 240 may be disposed in a first opening area OA1 of the bank 210.

The scattering pattern 240 may be disposed to correspond to the light emitting area EA1, EA2, and EA3 in a one-to-one correspondence, but not limited thereto. The scattering patterns 240 provided in the light emitting areas EA1, EA2, and EA3 of the subpixels SP1, SP2, and SP3 may be formed in one pattern connected to each other. When the scattering patterns 240 are formed in one pattern, the light emitted from the light emitting diode LED may be scattered and may proceed to the neighboring subpixels SP1, SP2, and SP3, whereby a color mixing may occur between the neighboring subpixels SP1, SP2, and SP3.

The scattering patterns 240 provided in the light emitting areas EA1, EA2, and EA3 of the subpixels SP1, SP2, and SP3 are spaced apart from each other, thereby preventing or at least reducing the color mixing between neighboring subpixels SP1, SP2, and SP3. The organic pattern 226 may be provided between each of the scattering patterns 240. Each of the scattering patterns 240 may have a circular edge, but not limited thereto. Each of the scattering patterns 240 may have a rectangular shape.

The scattering pattern 240 is provided over the light emitting diode LED and is configured to scatter the light emitted from the light emitting diode LED and to change the path of the light so that the light may proceed close to the front surface.

Specifically, the scattering pattern 240 may include a lower surface 240a, an upper surface 240b, and a side surface 240c. The scattering pattern 240 is provided over the first organic layer 222 so that the lower surface 240a of the scattering pattern 240 may be in contact with the first organic layer 222. The scattering pattern 240 is provided under the low refractive planarization layer 250 so that the upper surface 240b of the scattering pattern 240 may be in contact with the low refractive planarization layer 250.

Also, the scattering pattern 240 may include a second opening area OA2 provided in an area overlapping with the high refractive lens 230. The second opening area OA2 of the scattering pattern 240 may have a circular shape, but not limited thereto. The organic pattern 226 may be provided in the second opening area OA2 of the scattering pattern 240. That is, a flat surface 230a of the high refractive lens 230 may be in contact with the organic pattern 226. Accordingly, some of the light emitted from the light emitting diode LED may be incident on the flat surface 230a of the high refractive lens 230 without being scattered by the scattering pattern 240.

The scattering pattern 240 has the side surface 240c exposed by the second opening area OA2 and may be in contact with the organic pattern 226 at the exposed side surface 240c. The scattering pattern 240 may have the same thickness ‘Ts’ as the organic pattern 226.

Some of the light emitted from the light emitting diode LED may be incident on the side surface 240c or lower surface 240a of the scattering pattern 240, as shown in FIG. 11. The light L2 incident on the scattering pattern 240 may be refracted and scattered in the scattering pattern 240. The refracted and scattered light L2 may pass through the low refractive planarization layer 250 and the second substrate 300 and may be emitted to the outside. In the light emitting diode display device 10 according to another embodiment of the present disclosure, the light L2 incident on the scattering pattern 240 may be refracted and scattered in the scattering pattern 240 to the direction of the front surface (0°) so that it is possible to improve the luminance at the front surface (0°).

The fourth planarization layer 220 may be formed of an organic film such as acryl resin, epoxy resin, phenolic resin, polyamide resin, and polyimide resin. The first organic layer 222 and the second organic layer 224 of the fourth planarization layer 220 may be made of the same material or may be formed of different materials. The first organic layer 222 and the second organic layer 224 may have the same refractive index, but not limited thereto. The first organic layer 222 and the second organic layer 224 may have different refractive indices. Meanwhile, the scattering pattern 240 may include an organic material having a second refractive index and a plurality of scattering particles 241. The second refractive index may be less than 1.5 to 1.6 and may be smaller than the first refractive index. The organic pattern 226 of the second organic layer 224 and the organic material of the scattering pattern 240 may be made of the same material or may be formed of different materials. The organic pattern 226 of the second organic layer 224 and the organic material of the scattering pattern 240 may have the same refractive index, but not limited thereto. The organic pattern 226 of the second organic layer 224 and the organic material of the scattering pattern 240 may have different refractive indices.

The high refractive lens 230 may be convex toward the second substrate 300 on the fourth planarization layer 220. The high refractive lens 230 may be provided in each of light emitting areas EA1, EA2, and EA3 of each of the subpixels SP1, SP2, and SP3. That is, the high refractive lens 230 may be disposed in the first opening area OA1 of the bank 210. Also, the high refractive lens 230 may be provided to overlap the light emitting diode LED provided in each of the subpixels SP1, SP2, and SP3. The high refractive lens 230 may be disposed to correspond to the light emitting areas EA1, EA2, and EA3 in a one-to-one correspondence, but not limited thereto. The high refractive lens 230 may be arranged to correspond to the light emitting diode LED in a one-to-one correspondence, but not necessarily limited thereto.

The high refractive lens 230 is provided over the light emitting diode LED and is configured to refract the light emitted from the light emitting diode LED and to change the path of light so that the light may proceed close to the front surface. Herein, the front surface may indicate that the viewing angle is 0°.

In detail, the high refractive lens 230 may change a part of the light emitted from the light emitting diode LED. The light generated from the light emitting diode LED may pass through the fourth planarization layer 220, and a portion of the transmitted light may be incident on the high refractive lens 230. The high refractive lens 230 may collect the incident light and may emit the collected light to the outside.

The high refractive lens 230 may include the flat surface 230a and the curved surface 230b. The flat surface 230a of the high refractive lens 230 faces the light emitting diode LED and may be in contact with the fourth planarization layer 220, and more particularly, the upper surface of the organic pattern 226. The curved surface 230b of the high refractive lens 230 may be convex toward the second substrate 300.

Some of the light emitted from the light emitting diode LED may be incident on the flat surface 230a of the high refractive lens 230, as shown in FIG. 11. The light L1 incident on the flat surface 230a of the high refractive lens 230 is refracted and proceeds to the curved surface 230b of the high refractive lens 230 and may be refracted again on the curved surface 230b of the high refractive lens 230. The refracted light L1 may pass through the low refractive planarization layer 250 and the second substrate 300 and may be emitted to the outside. In the light emitting diode display device 10 according to one embodiment of the present disclosure, the refracting light L1 incident on the high refractive lens 230 is refracted from the flat surface 230a and the curved surface 230b of the high refractive lens 230 in the direction close to the front surface (0°).

This high refractive lens 230 may include an organic material having a first refractive index. The first refractive index may be greater than 1.5 and may be 1.6 or greater. The high refractive lens 230 may have a different refractive index from that of the fourth planarization layer 220, but not necessarily limited thereto. The high refractive lens 230 may have the same refractive index as that of the fourth planarization layer 220.

The light emitting diode display device 10 according to another embodiment of the present disclosure includes the high refractive lens 230 and the scattering pattern 240 on the light emitting diode LED so that it is possible to change the path of light emitted from the light emitting diode LED, thereby improving the luminance at the front surface (0°) and improving the luminance distribution for each inefficient viewing angle of the light emitting diode LED.

In detail, the light emitting diode display device 10 according to another embodiment of the present disclosure may change the path of light having a small angle among the light emitted from the light emitting diode LED by using the high refractive lens 230 provided over the light emitting diode LED. As shown in FIG. 11, the first light L1 having an angle less than or equal to a reference angle of the light emitted from the light emitting diode LED may be incident on the high refractive lens 230 and may be refracted by the high refractive lens 230 and then may be emitted to the outside. In the light emitting diode display device 10 according to another embodiment of the present disclosure, the first light L1 is refracted to the direction of the front surface (0°) by the high refractive lens 230 so that it is possible to improve the luminance at the front surface (0°).

The light emitting diode display device 10 according to another embodiment of the present disclosure may change the path of light having a large angle among the light emitted from the light emitting diode LED by using the scattering pattern 240 provided over the light emitting diode LED. As shown in FIG. 11, the second light L2 having an angle greater than the reference angle among the light emitted from the light emitting diode LED may be incident on the scattering pattern 240 and may be refracted and scattered by the scattering pattern 240 and then may be emitted to the outside. The light emitting diode display device 10 according to another embodiment of the present disclosure may further improve the luminance at the front surface (0°) by refracting and scattering the second light L2 in the direction close to the front surface (0°) by the scattering pattern 240.

As described above, the light emitting diode display device 10 according to another embodiment of the present disclosure includes the high refractive lens 230 and the scattering pattern 240 on the light emitting diode LED, thereby refracting the light emitted from the light emitting diode LED in the direction close to the front surface (0°) up to the light having a small angle as well as the light having a large angle. Accordingly, the light emitting diode display device 10 according to another embodiment of the present disclosure greatly improves the luminance at the front surface (0°) and prevents (or at least reduces) the light from being totally reflected in the low refractive planarization layer 250, thereby improving the light extraction efficiency.

In the light emitting diode display device 10 according to another embodiment of the present disclosure, the scattering pattern 240 is provided in the fourth planarization layer 220 provided under the high refractive lens 230, thereby increasing the thickness ‘Ts’ of the scattering pattern 240. According as the thickness ‘Ts’ of the scattering pattern 240 increases, the scattering effect may be increased. However, when the scattering pattern 240 is provided over the curved surface 230b of the high refractive lens 230 like the light emitting diode display device 10 according to one embodiment of the present disclosure shown in FIGS. 2 to 6, the scattering pattern 240 should have the thickness ‘Ts’ smaller than the height of the high refractive lens 230. Accordingly, the light emitting diode display device 10 according to one embodiment of the present disclosure shown in FIGS. 2 to 6 has a limitation in increasing the thickness ‘Ts’ of the scattering pattern 240.

In the light emitting diode display device 10 according to another embodiment of the present disclosure, the scattering pattern 240 is provided in the fourth planarization layer 220 so that it is possible to increase the thickness ‘Ts’ of the scattering pattern 240, thereby improving the light scattering effect in the scattering pattern 240.

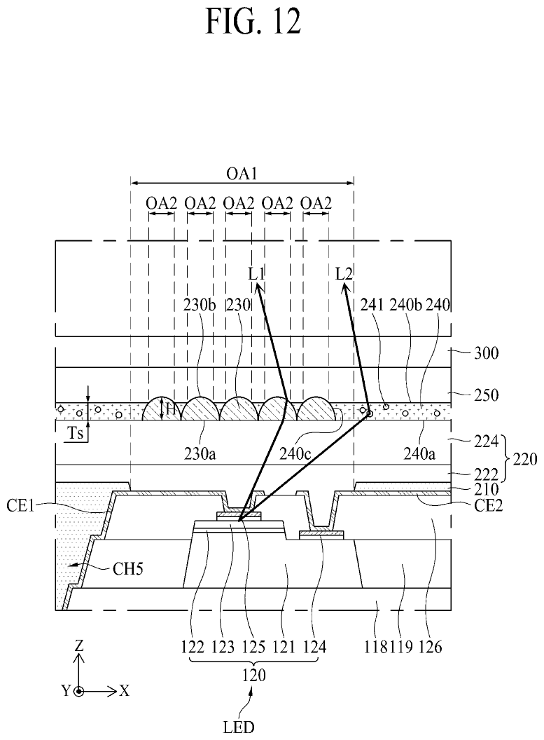

FIG. 12 is a cross sectional view illustrating a modified example along I-I′ of FIG. 2.

A light emitting diode display device 10 according to the modified embodiment of the present disclosure may include a driving transistor T, a plurality of insulating layers, a light emitting diode LED, a first connection electrode CE1, a second connection electrode CE2, a high refractive lens 230, a scattering pattern 240, a low refractive planarization layer 250, and a second substrate 300 on a first substrate 100.

The light emitting diode display device 10 according to the modified embodiment of the present disclosure is substantially the same as the light emitting diode display device 10 according to one embodiment of the present disclosure shown in FIGS. 2 to 6, except for only a high refractive lens 230 and a scattering pattern 240. Hereinafter, different configurations will be mainly described, and descriptions of substantially the same configurations will be omitted.

Referring to FIG. 12, the high refractive lens 230 may be convex toward the second substrate 300 on the fourth planarization layer 220. The high refractive lens 230 may be provided in each of light emitting areas EA1, EA2, and EA3 of each of subpixels SP1, SP2, and SP3. That is, the high refractive lens 230 may be disposed in a first opening area OA1 of a bank 210. Also, the high refractive lens 230 may be provided to overlap the light emitting diode LED provided in each of the subpixels SP1, SP2, and SP3. The plurality of high refractive lenses 230 may be provided in one light emitting area EA1, EA2, and EA3.

The plurality of high refractive lenses 230 may be provided over the light emitting diode LED and may be configured to refract light emitted from the light emitting diode LED and to change a path of light to be close to a front surface. Herein, the front surface may indicate that a viewing angle is 0°.

In detail, the plurality of high refractive lenses 230 may change a portion of the light emitted from the light emitting diode LED. The light generated from the light emitting diode LED may pass through the fourth planarization layer 220, and a portion of the transmitted light may be incident on at least one of the plurality of high refractive lenses 230. The plurality of high refractive lenses 230 may collect the incident light and emit the collected light to the outside.

Each of the plurality of high refractive lenses 230 may include a flat surface 230a and a curved surface 230b. The flat surface 230a of each of the plurality of high refractive lenses 230 may correspond to a surface facing the light emitting diode LED and may be in contact with an upper surface of the fourth planarization layer 220. The curved surface 230b of each of the plurality of high refractive lenses 230 may be convex toward the second substrate 300.

Some of the light transmitted through the fourth planarization layer 220 may be incident on at least one flat surface 230a of the plurality of high refractive lenses 230, as shown in FIG. 12. The light L1 incident on the flat surface 230a of the at least one high refractive lens 230 is refracted and proceeds to the curved surface 230b of the at least one high refractive lens 230 and then may be refracted again on the curved surface 230b of the at least one high refractive lens 230. The refracted light L1 may pass through the low refractive planarization layer 250 and the second substrate 300 and may be emitted to the outside. In the light emitting diode display device 10 according to the modified embodiment of the present disclosure, the light L1 incident on the high refractive lens 230 is refracted in the flat surface 230a and the curved surface 230b of at least one high refractive lens 230 to the direction of the front surface (0°), to thereby improve the luminance at the front surface (0°).

The plurality of high refractive lenses 230 may include an organic material having a first refractive index. The first refractive index may be greater than 1.5 and may be 1.6 or greater. The plurality of high refractive lenses 230 may have a different refractive index from the fourth planarization layer 220, but not limited thereto. The plurality of high refractive lenses 230 may have the same refractive index as that of the fourth planarization layer 220.

The scattering pattern 240 may be provided in each light emitting area EA1, EA2, and EA3 of each of the subpixels SP1, SP2, and SP3 together with the plurality of high refractive lenses 230. That is, the scattering pattern 240 may be disposed in the first opening area OA1 of the bank 210. Unlike the plurality of high refractive lenses 230, the scattering pattern 240 may not overlap the light emitting diode LED provided in each of the subpixels SP1, SP2, and SP3.

Unlike the high refractive lens 230, the scattering pattern 240 may be disposed to correspond to the light emitting area EA1, EA, and EA in a one-to-one correspondence, but not necessarily. The scattering patterns 240 provided in the light emitting areas EA1, EA2, and EA3 of the subpixels SP1, SP2, and SP3 are spaced apart from each other, thereby preventing or at least reducing a color mixture from occurring between the neighboring subpixels SP1, SP2, and SP3. In this case, each of the scattering patterns 240 may have a circular edge shape, but not limited thereto. Each of the scattering patterns 240 may have a rectangular edge shape.

The scattering pattern 240 is provided over the light emitting diode LED and is configured to scatter the light emitted from the light emitting diode LED and to change the path of light so that the light may proceed close to the front surface.

In detail, the scattering pattern 240 may include a lower surface 240a, an upper surface 240b, a first side surface 240c, and a second side surface 240d. The scattering pattern 240 is provided over the fourth planarization layer 220 so that the lower surface 240a may be in contact with the fourth planarization layer 220. The lower surface 240a of the scattering pattern 240 may be disposed on the same plane as the flat surface 230a of each of the plurality of high refractive lenses 230.

The scattering pattern 240 may be provided on the curved surface 230b of each of the plurality of high refractive lenses 230 and may include a plurality of second opening areas OA2 exposing at least a portion of the curved surface 230b of each of the plurality of high refractive lenses 230. Each of the plurality of second opening areas OA2 of the scattering pattern 240 may expose a region overlapped with the light emitting diode LED among the curved surfaces 230b of the corresponding high refractive lens 230.

The scattering pattern 240 may have the thickness ‘Ts’ which is smaller than the height ‘H’ of the plurality of high refractive lenses 230. Accordingly, the upper surface 240b of the scattering pattern 240 facing the second substrate 300 may be in contact with the low refractive planarization layer 250, and the first side surface 240c facing the curved surface 230b of the high refractive lens 230 may be in contact with the curved surface 230b of the high refractive lens 230. Also, the second side surface 240d of the scattering pattern 240 may be a surface facing the neighboring subpixels SP1, SP2, and SP3 and may be in contact with the low refractive planarization layer 250.

A part of the light transmitted through the fourth planarization layer 220 may be incident on the lower surface 240a of the scattering pattern 240. The light L2 incident on the lower surface 240a of the scattering pattern 240 may be refracted and scattered in the scattering pattern 240. The refracted and scattered light L2 may pass through the low refractive planarization layer 250 and the second substrate 300 and may be emitted to the outside. In the light emitting diode display device 10 according to the modified embodiment of the present disclosure, the light L2 incident on the scattering pattern 240 is refracted and scattered in the scattering pattern 240 to the direction of the front surface (0°) so that it is possible to improve the luminance at the front surface (0°).

The scattering pattern 240 may include an organic material having a second refractive index and a plurality of scattering particles 241. The second refractive index may be less than 1.5 to 1.6 and may be smaller than the first refractive index. The organic material of the scattering pattern 240 may have the same refractive index as that of the fourth planarization layer 220, but not limited thereto. The organic material of the scattering pattern 240 may have a different refractive index from that of the fourth planarization layer 220.

The light emitting diode display device 10 according to the modified embodiment of the present disclosure includes the high refractive lens 230 and the scattering pattern 240 on the light emitting diode LED so that it is possible to change the path of light emitted from the light emitting diode LED, thereby improving the luminance at the front surface (0°) and improving luminance distribution for each inefficient viewing angle of the light emitting diode LED.

In detail, the light emitting diode display device 10 according to the modified embodiment of the present disclosure may change the path of light having a small angle among the light emitted from the light emitting diode LED by using the high refractive lens 230 provided on the light emitting diode LED. As shown in FIG. 12, the first light L1 having an angle less than or equal to the reference angle among the light emitted from the light emitting diode LED may be incident on the high refractive lens 230 and may be refracted by the high refractive lens 230 and may be emitted the outside. In the light emitting diode display device 10 according to the modified embodiment of the present disclosure, the first light L1 is refracted in the direction close to the front surface (0°) by the high refractive lens 230 so that it is possible to improve the luminance at the front surface (0°).

The light emitting diode display device 10 according to the modified embodiment of the present disclosure may change the path of light having a large angle among the light emitted from the light emitting diode LED by using the scattering pattern 240 provided on the light emitting diode LED. As shown in FIG. 12, the second light L2 having an angle greater than the reference angle among the light emitted from the light emitting diode LED may be incident on the scattering pattern 240 and may be refracted and scattered by the scattering pattern 240 and then may be emitted to the outside. The light emitting diode display device 10 according to the modified embodiment of the present disclosure may further improve the luminance at the front surface (0°) by refracting and scattering the second light L2 in the direction close to the front surface (0°) by the scattering pattern 240.

As described above, the light emitting diode display device 10 according to the modified embodiment of the present disclosure has the high refractive lens 230 and the scattering pattern 240 on the light emitting diode LED, thereby refracting the light emitted from the light emitting diode LED in the direction close to the front surface (0°) up to the light having a small angle as well as the light having a large angle. Accordingly, the light emitting diode display device 10 according to the modified embodiment of the present disclosure greatly improves luminance at the front surface (0°) and prevents (or at least reduces) the light from being totally reflected in the low refractive planarization layer 250, thereby improving the light extraction efficiency.

Also, in the light emitting diode display device 10 according to the modified embodiment of the present disclosure, the plurality of high refractive lenses 230 may be provided in one light emitting area EA1, EA2, and EA3. Thus, even when a transfer tolerance occurs due to the light emitting diode disposed at an accurate position, it is possible to prevent or at least reduce the luminance distribution for each viewing angle from being biased to one side.

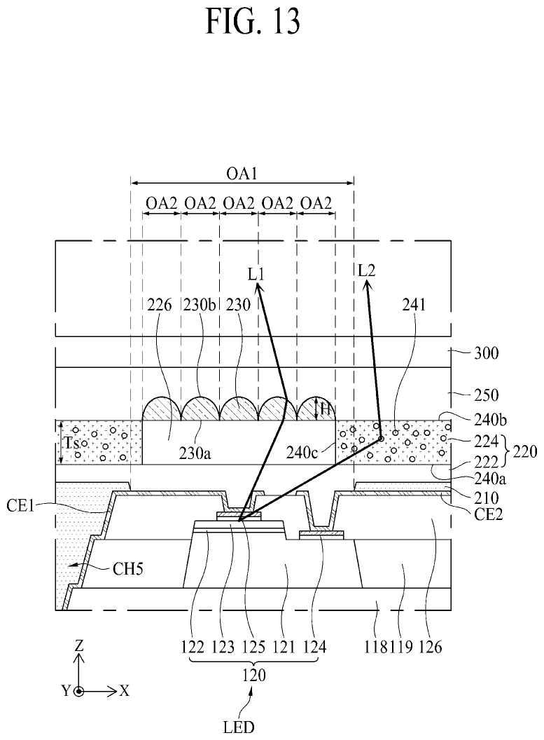

FIG. 13 is a cross sectional view illustrating another modified example along I-I′ of FIG. 2.

The light emitting diode display device 10 according to another modified embodiment of the present disclosure may include a driving transistor T, a plurality of insulating layers, a light emitting diode LED, a first connection electrode CE1, a second connection electrode CE2, a high refractive lens 230, a scattering pattern 240, a low refractive planarization layer 250, and a second substrate 300 on a first substrate 100.

The light emitting diode display device 10 according to another modified embodiment of the present disclosure is substantially the same as the light emitting diode display device 10 according to one embodiment of the present disclosure shown in FIGS. 2 to 6, except for only fourth planarization layer 220, high refractive lens 230, and scattering pattern 240.

On the other hand, the high refractive lens 230 provided in the light emitting diode display device 10 according to another modified embodiment of the present disclosure is substantially the same as the high refractive lens 230 provided in the light emitting diode display device 10 according to the modified embodiment of the present disclosure shown in FIG. 12, whereby a detailed description thereof will be omitted. Also, the fourth planarization layer 220 and the scattering pattern 240 provided in the light emitting diode display device 10 according to another modified embodiment of the present disclosure are substantially the same as the fourth planarization layer 220 and the scattering pattern 240 provided in the light emitting diode display device 10 according to another embodiment of the present disclosure shown in FIG. 11, whereby a detailed description thereof will be omitted.

In the same manner as the light emitting diode display devices 10 according to other embodiments of the present disclosure, the light emitting diode display device 10 according to another embodiment of the present disclosure includes the high refractive lens 230 and the scattering pattern 240 on the light emitting diode LED so that it is possible to change a path of light emitted from a light emitting diode LED, thereby improving a luminance at a front surface (0°) and improving a luminance distribution for each inefficient viewing angle of the light emitting diode LED.

Specifically, the light emitting diode display device 10 according to another modified embodiment of the present disclosure may change a path of light having a small angle among the light emitted from the light emitting diode LED by using the high refractive lens 230 provided on the light emitting diode LED. A first light L1 having an angle less than or equal to a reference angle among the light emitted from the light emitting diode LED may be incident on the high refractive lens 230 and may be refracted by the high refractive lens 230 and then may be emitted to the outside. In the light emitting diode display device 10 according to another modified embodiment of the present disclosure, the first light L1 may be refracted in the direction close to the front surface (0°) by the high refractive lens 230 so that it is possible to improve the luminance at the front surface (0°).

The light emitting diode display device 10 according to another modified embodiment of the present disclosure may change a path of light having a large angle among the light emitted from the light emitting diode LED by using the scattering pattern 240 provided on the light emitting diode LED. A second light L2 having an angle greater than a reference angle among the light emitted from the light emitting diode LED may be incident on the scattering pattern 240 and may be refracted and scattered by the scattering pattern 240 and then may be emitted to the outside. In the light emitting diode display device 10 according to another modified embodiment of the present disclosure, the second light L2 is refracted and scattered in the direction close to the front surface (0°) by the scattering pattern 240 so that it is possible to further improve the luminance at the front surface (0°).

As described above, the light emitting diode display device 10 according to another modified embodiment of the present disclosure has the high refractive lens 230 and the scattering pattern 240 on the light emitting diode LED, thereby refracting the light emitted from the light emitting diode LED in the direction close to the front surface (0°) up to the light having a small angle as well as the light having a large angle. Accordingly, the light emitting diode display device 10 according to another modified embodiment of the present disclosure greatly improves the luminance at the front surface (0°) and prevents (or at least reduces) the light from being totally reflected in the low refractive planarization layer 250, thereby improving the light extraction efficiency.

In the same manner as the light emitting diode display device 10 shown in FIG. 11, the light emitting diode display device 10 according to another modified embodiment of the present disclosure has the scattering pattern 240 which is provided in the fourth planarization layer 220 provided under the high refractive lens 230, thereby increasing the thickness ‘Ts’ of the scattering pattern 240. According as the thickness ‘Ts’ of the scattering pattern 240 increases, the scattering effect may be increased.

Also, in the light emitting diode display device 10 according to another modified embodiment of the present disclosure, the plurality of high refractive lenses 230 may be provided in one light emitting area EA1, EA2, and EA3, in the same manner as the light emitting diode display device 10 shown in FIG. 12. Thus, even when a transfer tolerance occurs due to the light emitting diode disposed at an accurate position, it is possible to prevent or at least reduce the luminance distribution for each viewing angle from being biased to one side.

On the other hand, FIGS. 3 to 6 and FIGS. 11 to 13 show that the light emitting diode LED has a top emission structure, but not necessarily. The light emitting diode display device 10 according to the embodiments illustrated in FIGS. 3 to 6 and FIGS. 11 to 13 may also be applied with a light emitting diode LED having a bottom emission structure.

According to the present disclosure, the high refractive lens is provided on the light emitting diode, so that the light having the small angle among the light emitted from the light emitting diode may be refracted to the front surface direction by the high refractive lens and may be emitted to the outside. Also, the scattering pattern is provided on the light emitting diode, so that the light having the large angle among the light emitted from the light emitting diode may be refracted and scattered to the front surface direction by the scattering pattern and may be emitted to the outside. Accordingly, it is possible to greatly improve the front luminance.

According to the present disclosure, it is possible to prevent or at least reduce the light emitted from the light emitting diode from being totally reflected in the low refractive planarization layer, thereby improving the light extraction efficiency. Accordingly, it is possible to realize high luminous efficiency with low power consumption, and furthermore, to reduce power consumption.

In addition, the planarization layer is provided between the light emitting diode and the high refractive lens so that it is possible to secure the optical distance between the light emitting diode and the high refractive lens, thereby increasing the light collecting effect of the high refractive lens.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A light emitting diode display device comprising:
a light emitting diode over a substrate;
a lens over the light emitting diode, the lens having a convex curved surface; and
a scattering pattern including an opening area exposing at least a portion of the convex curved surface of the lens.

2. The light emitting diode display device according to claim 1, wherein the scattering pattern includes a plurality of scattering particles.

3. The light emitting diode display device according to claim 1, wherein the scattering pattern is over the convex curved surface of the lens.

4. The light emitting diode display device according to claim 1, wherein the lens further includes a flat surface facing the light emitting diode, the flat surface of the lens on a same plane as a lower surface of the scattering pattern.

5. The light emitting diode display device according to claim 1, wherein a thickness of the lens is greater than a thickness of the scattering pattern.

6. The light emitting diode display device according to claim 1, wherein the light emitting diode is in a region that overlaps an area of the lens, and the region is smaller than the area of the lens.

7. The light emitting diode display device according to claim 1, wherein the lens corresponds to the light emitting diode in a one-to-one correspondence.

8. The light emitting diode display device according to claim 1, wherein a plurality of lenses are over one light emitting diode.

9. The light emitting diode display device according to claim 1, wherein light having an angle less than or equal to a reference angle among light emitted from the light emitting diode is incident to the lens, and light having an angle greater than the reference angle is incident on the scattering pattern.

10. The light emitting diode display device according to claim 9, wherein the lens refracts light incident on the lens to a direction of front surface, the front surface indicates a position where a viewing angle is 0°.

11. The light emitting diode display device according to claim 9, wherein the scattering pattern is configured to refract and scatter light incident on the scattering pattern to a direction of front surface, the front surface indicates a position where a viewing angle is 0°

12. The light emitting diode display device according to claim 9, wherein the reference angle is an angle between a range of 400 and about 50°.

13. The light emitting diode display device according to claim 1, further comprising:
a first planarization layer between the light emitting diode and the lens.

14. The light emitting diode display device according to claim 13, wherein a thickness of the first planarization layer is greater than a value obtained by subtracting a half of a width of the light emitting diode from a radius of the lens.

15. The light emitting diode display device according to claim 13, wherein while a center of the lens and a center of a light emitting layer of the light emitting diode are aligned on a same line, a thickness of the first planarization layer satisfy a following Equation:
$$tan ( {θ}_{i} ) = \frac{{T}_{p}}{r - \frac{d}{2}}$$
wherein θᵢ denotes a first angle between a straight line perpendicular to the substrate and a straight line passing through one end of the lens from one end of the light emitting layer of the light emitting diode, Tp denotes the thickness of the first planarization layer, r denotes a radius of the lens, and d denotes a length of the light emitting diode.

16. The light emitting diode display device according to claim 13, wherein the first planarization layer has the scattering pattern in an area which is non-overlapping with the light emitting diode.

17. The light emitting diode display device according to claim 1, further comprising:
a second planarization layer over the lens and the scattering pattern.

18. The light emitting diode display device according to claim 17, wherein the lens has a first refractive index, and the second planarization layer has a second refractive index that is less than the first refractive index.

19. The light emitting diode display device according to claim 17, wherein the second planarization layer is in contact with at least a portion of the convex curved surface of the lens.

20. The light emitting diode display device according to claim 17, wherein light directly incident from the lens to the second planarization layer among light emitted from the light emitting diode is partially reflected by the second planarization layer.

21. The light emitting diode display device according to claim 20, wherein a thickness of the scattering pattern satisfies a following Equation:
$$sin ( \frac{{n}_{low}}{{n}_{high}} sin ( {θ}_{out} - atan ( \frac{R - α}{\sqrt{2 R α - {α}^{2}}} ) ) ) + atan ( \frac{R - α}{\sqrt{2 R α - {α}^{2}}} ) = asin ( \frac{{n}_{p}}{{n}_{high}} sin ( atan ( \frac{\sqrt{2 R α - {α}^{2}} + d / 2}{R - α + {T}_{p}} ) ) )$$
wherein n_{low} represents a refractive index of the second planarization layer, θₒᵤₜ represents a second angle between light transmitted to the second planarization layer and a straight line perpendicular to a normal line of the light emitting diode at a point where the convex curved surface of the lens meets an upper surface of the scattering pattern, n_{high} represents a refractive index of the lens, R represents a radius of curvature of the lens, a represent a difference between a height of the lens and the thickness of the scattering pattern, np represents a refractive index of a first planarization layer between the light emitting diode and the lens, Tp represents a thickness of the first planarization layer, and d represents a length of the light emitting diode.

22. The light emitting diode display device according to claim 1, wherein the light emitting diode is in a region in the opening area of the scattering pattern.

23. The light emitting diode display device according to claim 1, wherein the opening area of the scattering pattern has a circular shape.

24. The light emitting diode display device according to claim 1, wherein the lens has a first refractive index, the scattering pattern includes an organic material having a second refractive index, and the second refractive index is less than the first refractive index.
